(19) United States
(12) Patent Application Publication
(10) Pub. No.: US 2026/0040662 A1
(43) Pub. Date: Feb. 5, 2026

(54) SEMICONDUCTOR DEVICE AND MANUFACTURING METHOD THEREFOR

(71) Applicant: Kioxia Corporation, Tokyo (JP)

(72) Inventor: Junichi SHIBATA, Yokkaichi Mie (JP)

(21) Appl. No.: 19/068,093

(22) Filed: Mar. 3, 2025

(30) Foreign Application Priority Data
Jul. 30, 2024 (JP) 2024-123677

(51) Int. Cl. H10D 84/80; H10D 84/01

(52) U.S. Cl. CPC H10D 84/811; H10D 84/01

(57) ABSTRACT

According to one embodiment, a semiconductor device includes: a substrate including a first upper surface; and an element isolation area provided in the substrate and including a second upper surface that is higher than the first upper surface. The device further includes at least one transistor including a gate insulating film provided above the first upper surface of the substrate and a gate electrode provided above the gate insulating film. The device further includes a resistor including a conductive layer provided above the second upper surface of the element isolation area. The device further includes a capacitor including a first dielectric layer provided above the first upper surface of the substrate, a first electrode layer provided above the first dielectric layer, a second dielectric layer provided above the first electrode layer, and a second electrode layer provided above the second dielectric layer.

### CROSS-REFERENCE TO RELATED APPLICATION

This application is based upon and claims the benefit of priority from Japanese Patent Application No. 2024-123677, filed Jul. 30, 2024, the entire contents of which are incorporated herein by reference.

### FIELD

Embodiments described herein relate generally to a semiconductor device and a manufacturing method therefor.

### BACKGROUND

When devices such as transistors, resistors, and capacitors are formed on substrates, it may be difficult to form devices that have appropriate performance in some cases. For example, when thicknesses of conductive layers for resistance are thick, it is difficult to increase values of resistance. It is also difficult to increase capacitance of capacitors without increasing areas of the capacitors in a plan view.

### DESCRIPTION OF THE DRAWINGS

FIGS. 1A to 1F are sectional views illustrating a structure of a semiconductor device according to a first embodiment;

FIGS. 2A and 2B are sectional views (1/3) illustrating details of the structure of the semiconductor device according to the first embodiment;

FIGS. 3A and 3B are sectional views (2/3) illustrating details of the structure of the semiconductor device according to the first embodiment;

FIGS. 4A and 4B are sectional views (3/3) illustrating details of the structure of the semiconductor device according to the first embodiment;

FIGS. 5A to 5C are plan views illustrating three examples of the structure of the semiconductor device according to the first embodiment;

FIGS. 6A to 6F are sectional views illustrating a structure of a semiconductor device according to a comparative example of the first embodiment;

FIGS. 7A to 7F are sectional views (1/19) illustrating a method of manufacturing the semiconductor device according to the first embodiment;

FIGS. 8A to 8F are sectional views (2/19) illustrating the method of manufacturing the semiconductor device according to the first embodiment;

FIGS. 9A to 9F are sectional views (3/19) illustrating the method of manufacturing the semiconductor device according to the first embodiment;

FIGS. 10A to 10F are sectional views (4/19) illustrating the method of manufacturing the semiconductor device according to the first embodiment;

FIGS. 11A to 11F are sectional views (5/19) illustrating the method of manufacturing the semiconductor device according to the first embodiment;

FIGS. 12A to 12F are sectional views (6/19) illustrating the method of manufacturing the semiconductor device according to the first embodiment;

FIGS. 13A to 13F are sectional views (7/19) illustrating the method of manufacturing the semiconductor device according to the first embodiment;

FIGS. 14A to 14F are sectional views (8/19) illustrating the method of manufacturing the semiconductor device according to the first embodiment;

FIGS. 15A to 15F are sectional views (9/19) illustrating the method of manufacturing the semiconductor device according to the first embodiment;

FIGS. 16A to 16F are sectional views (10/19) illustrating the method of manufacturing the semiconductor device according to the first embodiment;

FIGS. 17A to 17F are sectional views (11/19) illustrating the method of manufacturing the semiconductor device according to the first embodiment;

FIGS. 18A to 18F are sectional views (12/19) illustrating the method of manufacturing the semiconductor device according to the first embodiment;

FIGS. 19A to 19F are sectional views (13/19) illustrating the method of manufacturing the semiconductor device according to the first embodiment;

FIGS. 20A to 20F are sectional views (14/19) illustrating the method of manufacturing the semiconductor device according to the first embodiment;

FIGS. 21A to 21F are sectional views (15/19) illustrating the method of manufacturing the semiconductor device according to the first embodiment;

FIGS. 22A to 22F are sectional views (16/19) illustrating the method of manufacturing the semiconductor device according to the first embodiment;

FIGS. 23A to 23F are sectional views (17/19) illustrating the method of manufacturing the semiconductor device according to the first embodiment;

FIGS. 24A to 24F are sectional views (18/19) illustrating the method of manufacturing the semiconductor device according to the first embodiment;

FIGS. 25A to 25F are sectional views (19/19) illustrating the method of manufacturing the semiconductor device according to the first embodiment;

FIGS. 26A to 26F are sectional views (1/3) illustrating a method of manufacturing a semiconductor device according to a first modified example of the first embodiment;

FIGS. 27A to 27F are sectional views (2/3) illustrating the method of manufacturing the semiconductor device according to the first modified example of the first embodiment;

FIGS. 28A to 28F are sectional views (3/3) illustrating the method of manufacturing the semiconductor device according to the first modified example of the first embodiment;

FIGS. 29A and 29B are sectional views illustrating a structure of a semiconductor device according to a second modified example of the first embodiment;

FIG. 30 is a sectional view illustrating a structure of a semiconductor device according to a third modified example of the first embodiment;

FIGS. 31A to 31C are plan and sectional views illustrating a structure of a semiconductor device according to a fourth modified example of the first embodiment;

FIG. 32 is a sectional view illustrating a structure of a semiconductor device according to a second embodiment;

FIG. 33 is an enlarged sectional view illustrating the structure of the semiconductor device according to the second embodiment;

FIG. 34 is a sectional view (1/2) illustrating a method of manufacturing the semiconductor device according to the second embodiment;

FIG. 35 is a sectional view (2/2) illustrating the method of manufacturing the semiconductor device according to the second embodiment;

FIG. 36 is a block diagram illustrating a configuration of a memory system according to a third embodiment;

FIG. 37 is a circuit diagram illustrating a configuration of a memory cell array according to the third embodiment;

FIG. 38 is a circuit diagram illustrating a configuration of a voltage generation circuit according to the third embodiment;

FIG. 39 is a circuit diagram illustrating a configuration of a resistor according to the third embodiment; and

FIG. 40 is a circuit diagram illustrating a configuration of a charge pump according to the third embodiment.

### DETAILED DESCRIPTION

Embodiments provide a semiconductor device and a manufacturing method therefor capable of forming a device that has appropriate performance.

In general, according to one embodiment, a semiconductor device includes: a substrate including a first upper surface; and an element isolation area provided in the substrate and including a second upper surface higher than the first upper surface. The device further includes at least one transistor including a gate insulating film provided above the first upper surface of the substrate and a gate electrode provided above the gate insulating film. The device further includes a resistor including a conductive layer provided above the second upper surface of the element isolation area. The device further includes a capacitor including a first dielectric layer provided above the first upper surface of the substrate, a first electrode layer provided above the first dielectric layer, a second dielectric layer provided above the first electrode layer, and a second electrode layer provided above the second dielectric layer.

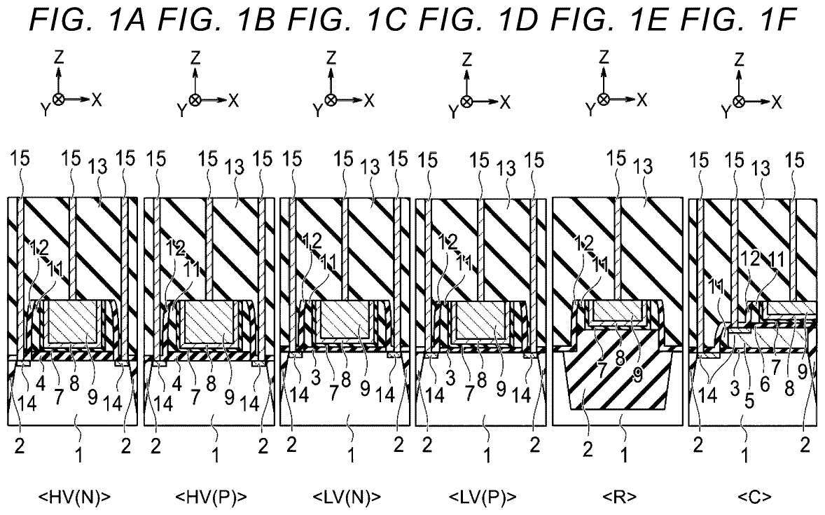

Hereinafter, embodiments of the disclosure will be described with reference to the drawings. In FIGS. 1A to 40, the same reference numerals are given to the same configurations and repeated description thereof will be omitted.

### First Embodiment

FIGS. 1A to 1F are sectional views illustrating a structure of a semiconductor device according to a first embodiment.

The semiconductor device according to the embodiment includes a transistor HV(N) illustrated in FIG. 1A, a transistor HV(P) illustrated in FIG. 1B, a transistor LV(N) illustrated in FIG. 1C, a transistor LV(P) illustrated in FIG. 1D, a resistor (resistance element) R illustrated in FIG. 1E, and a capacitor (capacitive element) C illustrated in FIG. 1F. The transistors HV(N) and HV(P) are examples of a first transistor and the transistors LV(N) and LV(P) are examples of a second transistor.

The transistor HV(N) is an N type high-voltage transistor. The transistor HV(P) is a P type high-voltage transistor. The transistor LV(N) is an N type low-voltage transistor. The transistor LV(P) is a P type low-voltage transistor. The transistors HV(N), HV(P), LV(N), LV(P), the resistor R, and the capacitor C according to the embodiment are formed of common materials, as illustrated in FIGS. 1A to 1F. Hereinafter, details of the materials will be described.

As illustrated in FIGS. 1A to 1F, the semiconductor device according to the embodiment includes a substrate 1, a plurality of element isolation areas 2, an insulating film 3, an insulating film 4, a semiconductor layer 5, an insulating film 6, an insulating film 7, an electrode material ground layer 8, an electrode material layer 9, a side wall insulating film 11, a liner insulating film 12, an interlayer insulating film 13, a plurality of silicide regions 14, and a plurality contact plugs 15. The insulating film 3 is an example of first and third insulating films, the insulating film 7 is an example of second, fourth, and fifth insulating films, and the insulating film 6 is an example of a sixth insulating film. The electrode material ground layer 8 is an example of a first conductive layer and the electrode material layer 9 is an example of a second conductive layer.

### [Substrate 1]

The substrate 1 is, for example, a semiconductor substrate such as a silicon (Si) substrate. FIGS. 1A to 1F illustrate six different portions of the same substrate 1. As illustrated in FIGS. 1A to 1F, the X and Y directions are vertical to each other in parallel to an upper surface of the substrate 1 and the Z direction is vertical to the upper surface of the substrate 1. In the present specification, the +Z direction serves as the upper direction and the −z direction serves as the lower direction. The −Z direction may match or may not match the gravity direction.

The substrate 1 according to the embodiment has an upper surface with a substantially uniform height (Z direction). Here, the upper surface of the substrate 1 illustrated in FIGS. 1A and 1B is lower than the upper surface of the substrate 1 illustrated in FIGS. 1C to 1F. The upper surface of the substrate 1 illustrated in FIGS. 1A and 1B is an example of first and third upper surfaces, and the upper surface of the substrate 1 illustrated in FIGS. 1C to 1F is an example of first and fourth upper surfaces. In FIGS. 1A to 1F, the upper surface of the substrate 1 below the element isolation area 2 is lower than the upper surface of the other portions of the substrate 1.

### [Element Isolation Area 2]

Each element isolation area 2 is formed in the substrate 1. The transistor HV(N) illustrated in FIG. 1A is formed above the substrate 1 between two element isolation areas 2. The same applies to the transistors HV(P), LV(N), and LV(P) illustrated in FIGS. 1B to 1D. The resistor R illustrated in FIG. 1E is formed above one element isolation area 2. The capacitor C illustrated in FIG. 1F is formed above the substrate 1 between two element isolation areas 2.

In the embodiment, the element isolation area 2 is formed with the same insulating film (for example, a silicon oxide film (SiO₂ film)). Specifically, the element isolation area 2 is formed by forming a trench in the substrate 1 and burying the insulating film in the trench. The insulating film is referred to as, for example, a shallow trench isolation (STI) insulating film. More details of the element isolation area 2, such as a timing at which the element isolation area 2 is formed will be described below.

The element isolation area 2 illustrated in FIG. 1E includes the upper surface of the substrate 1 illustrated in FIGS. 1A and 1B or the upper surface higher than the upper surface of the substrate 1 illustrated in FIGS. 1C and 1F. Hereinafter, the upper surface of the element isolation area 2 illustrated in FIG. 1E is also referred to as an uppermost surface. The uppermost surface of the element isolation area 2 illustrated in FIG. 1E is an example of a second upper surface. [Insulating Films 3 and 4]

The insulating films 3 and 4 are formed above the substrate 1. Here, a thickness of the insulating film 4 is higher than thickness of the insulating film 3. The insulating films 3 and 4 are, for example, SiO₂ films. The upper surface of the substrate 1 below the insulating film 4 is lower than the upper surface of the substrate 1 below the insulating film 3.

In FIG. 1A, the insulating film 4, the insulating film 7, the electrode material ground layer 8, and the electrode material layer 9 are formed in this order above the substrate 1. In FIG. 1A, the insulating films 4 and 7 between the upper surface of the substrate 1 and the lower surface of the electrode material ground layer 8 function as a gate insulating film of the transistor HV(N), and the electrode material ground layer 8 and the electrode material layer 9 function as a gate electrode of the transistor HV(N). The same applies to the transistor HV(P) illustrated in FIG. 1B.

In FIG. 1C, the insulating film 3, the insulating film 7, the electrode material ground layer 8, and the electrode material layer 9 are formed in this order above the substrate 1. In FIG. 1C, the insulating films 3 and 7 between the upper surface of the substrate 1 and the lower surface of the electrode material ground layer 8 function as a gate insulating film of the transistor LV(N), and the electrode material ground layer 8 and the electrode material layer 9 function as a gate electrode of the transistor LV(N). The same applies to the transistor LV(P) illustrated in FIG. 1D.

The gate insulating film of the transistor HV(N) includes the insulating films 4 and 7 and the gate insulating film of the transistor LV(N) includes the insulating films 3 and 7. In the embodiment, since the thickness of the insulating film 4 is higher than the thickness of the insulating film 3, the thickness of the gate insulating film of the transistor HV(N) is higher than the thickness of the gate insulating film of the transistor LV(N). The same applies to a gate insulating film of the transistor HV(P) and a gate insulating film of the transistor LV(P).

In FIG. 1F, the insulating film 3, the semiconductor layer 5, the insulating film 6, the insulating film 7, the electrode material ground layer 8, and the electrode material layer 9 are formed on the substrate 1 in this order. In FIG. 1F, the substrate 1 functions as a lower electrode layer of the capacitor C, the semiconductor layer 5 functions as an intermediate electrode layer of the capacitor C, and the electrode material ground layer 8 and the electrode material layer 9 function as an upper electrode layer of the capacitor C. The insulating film 3 between the upper surface of the substrate 1 and the lower surface of the semiconductor layer 5 function as a lower dielectric layer of the capacitor C, and the insulating films 6 and 7 between the upper surface of the semiconductor layer 5 and the lower surface of the electrode material ground layer 8 function as an upper dielectric layer of the capacitor C. The capacitor C according to the embodiment includes a lower capacitor between the lower electrode layer and the intermediate electrode layer and an upper capacitor between the intermediate electrode layer and the upper electrode layer. The lower dielectric layer, the intermediate electrode layer, the upper dielectric layer, and the upper electrode layer are examples of a first dielectric layer, a first electrode layer, a second dielectric layer, and a second electrode layer, respectively. The lower capacitor is an example of a first capacitor and the upper capacitor is an example of a second capacitor.

The more details of the semiconductor layer 5, the insulating film 6, the insulating film 7, the electrode material ground layer 8, and the electrode material layer 9 will be described below.

### [Semiconductor Layer 5]

The semiconductor layer 5 is formed above the insulating film 3 in FIG. 1F. The semiconductor layer 5 is, for example, a polysilicon layer. In the embodiment, a height of the upper surface of the semiconductor layer 5 is the same as a height of the upper surface of the element isolation area 2 on the right of FIG. 1F. A height of the upper surface of the element isolation area 2 on the right of FIG. 1F is the same as a height of the uppermost surface of the element isolation area 2 illustrated in FIG. 1E.

### [Insulating Film 6]

The insulating film 6 is formed above the semiconductor layer 5 in FIG. 1F. The insulating film 6 is formed above the element isolation area 2 on the right of FIG. 1F. The insulating film 6 is, for example, a SiO₂ film.

### [Insulating Film 7]

The insulating film 7 is formed above the insulating film 4 in FIGS. 1A and 1B, and is formed above the insulating film 3 in FIGS. 1C and 1D. The insulating film 7 is further formed on the uppermost surface of the element isolation area 2 in FIG. 1E and is formed above the insulating film 6 in FIG. 1F. The insulating film 7 is, for example, a high-k insulating film such as a metal oxide film. An example of the high-k insulating film is a hafnium (Hf) oxide film, a zirconium (Zr) oxide film, a Hf silicate film, a Zr silicate film, a Hf silicate nitride film, or a Zr silicate nitride film. The high-k insulating film may contain an additive element such as aluminum (Al) or lanthanum (La).

In each of FIGS. 1A to 1F, the insulating film 7 is formed on a lower surface and a side surface of the electrode material ground layer 8, and the electrode material ground layer 8 is formed on a lower surface and a side surface of the electrode material layer 9. In each of FIGS. 1A and 1B, the insulating film 7, the electrode material ground layer 8, and the electrode material layer 9 in the structure are formed by burying the insulating film 7, the electrode material ground layer 8, and the electrode material layer 9 in this order in a recess portion formed by the insulating film 4 and the side wall insulating film 11. In each of FIGS. 1C and 1D, the insulating film 7, the electrode material ground layer 8, and the electrode material layer 9 in the structure are formed by burying the insulating film 7, the electrode material ground layer 8, and the electrode material layer 9 in this order in a recess portion formed by the insulating film 3 and the side wall insulating film 11. In FIG. 1E, the insulating film 7, the electrode material ground layer 8, and the electrode material layer 9 in the structure are formed by burying the insulating film 7, the electrode material ground layer 8, and the electrode material layer 9 in this order in a recess portion formed by the element isolation area 2 and the side wall insulating film 11. In FIG. 1F, the insulating film 7, the electrode material ground layer 8, and the electrode material layer 9 in the structure are formed by burying the insulating film 7, the electrode material ground layer 8, and the electrode material layer 9 in this order in a recess portion formed by the insulating film 6 and the side wall insulating film 11.

### [Electrode Material Ground Layer 8]

The electrode material ground layer 8 is formed on an upper surface and a side surface of the insulating film 7 in each of FIGS. 1A to 1F. The electrode material ground layer 8 is, for example, a stacked film including a plurality of metal layers. In this case, examples of the metal layers included in the electrode material ground layer 8 are a titanium nitride (TiN) film, a titanium oxynitride (TiNO) film, titanium carbide (TiC) film, a titanium aluminum carbide (TiAlC) film, and a titanium silicon oxynitride carbide (TiSiNOC) film.

In the embodiment, a height of the upper surface of the semiconductor layer 5 is the same as a height of the uppermost surface of the element isolation area 2 illustrated in FIG. 1E. Accordingly, a height of the lower surface of the electrode material ground layer 8 is higher than the height of the uppermost surface of the element isolation area 2 illustrated in FIG. 1E. In other words, a height of the upper surface of the intermediate electrode layer of the capacitor C is the same as the height of the uppermost surface of the element isolation area 2 and a height of a lower surface of the upper electrode layer of the capacitor C is higher than a height of the uppermost surface of the element isolation area 2.

### [Electrode Material Layer 9]

The electrode material layer 9 is formed on an upper surface and a side surface of the electrode material ground layer 8 in each of FIGS. 1A to 1F. The electrode material layer 9 is, for example, a metal layer such as a tungsten (W) layer, an aluminum (Al) layer, or a titanium aluminum carbide (TiAlC) layer.

The resistor R: illustrated in FIG. 1E includes a conductive layer formed on the uppermost surface of the element isolation area 2 with the insulating film 7 interposed therebetween. The conductive layer includes the electrode material ground layer 8 and the electrode material layer 9 and functions as the resistor R that has a predetermined resistance value.

When the semiconductor device according to the embodiment is manufactured, an upper surface of the electrode material layer 9 is flattened by chemical mechanical polishing (CMP) along with the electrode material ground layer 8 or the insulating film 7. Therefore, the electrode material layer 9 illustrated in FIGS. 1A to 1F includes the upper surface at a substantially uniform height.

### [Side Wall Insulating Film 11 and Liner Insulating Film 12]

The side wall insulating film 11 and the liner insulating film 12 are formed in this order on each side surface of the insulating film 7 in each of FIGS. 1A to 1F. The side wall insulating film 11 and the liner insulating film 12 are further formed in this order on a side surface of the semiconductor layer 5 in FIG. 1F. The liner insulating film 12 is further formed on upper surfaces or the like of the substrate 1, the element isolation area 2 and the semiconductor layer 5. The side wall insulating film 11 is, for example, a stacked film including a plurality of insulating films. The liner insulating film 12 is, for example, a stacked film including a plurality of insulating films.

### [Interlayer Insulating Film 13]

The interlayer insulating film 13 is formed on the substrate 1 to cover element the isolation area 2, the insulating film 3, the insulating film 4, the semiconductor layer 5, the insulating film 6, the insulating film 7, the electrode material ground layer 8, the electrode material layer 9, the side wall insulating film 11, and the liner insulating film 12. The interlayer insulating film 13 is, for example, a SiO₂ film.

[Silicide region 14]

Each silicide region 14 is formed in the substrate 1 or the semiconductor layer 5. Each silicide region 14 is, for example, a nickel silicide (NiSi) region, a nickel platinum silicide (NiPtSi) region, or a cobalt silicide (CoSi) region. Each silicide region 14 may also contain an additive element such as germanium (Ge) or fluorine (F).

In FIG. 1A, two silicide regions 14 are formed in the substrate 1 such that gate electrodes (the electrode material ground layer 8 and the electrode material layer 9) are interposed therebetween. The same applies to FIGS. 1B to 1D. In FIG. 1F, two silicide regions 14 are formed in the substrate 1 and the semiconductor layer 5.

### [Contact Plug 15]

Each contact plug 15 is formed in the interlayer insulating film 13. Specifically, each contact plug 15 is formed on the silicide region 14 provided in the substrate 1, the silicide region 14 formed in the semiconductor layer 5, or on the electrode material layer 9. Each contact plug 15 is, for example, a metal plug.

In FIG. 1A, three contact plugs 15 are formed on one silicide region 14, the other silicide region 14, and the electrode material layer 9. The contact plugs 15 are used for control a source region and a drain region of the transistor HV(N) and the gate electrodes (the electrode material ground layer 8 and the electrode material layer 9). The same applies to FIGS. 1B to 1D.

In FIG. 1E, actually, two or more contact plugs 15 are formed on the electrode material layer 9. FIG. 1E illustrates one of the contact plugs 15. More details of the contact plugs 15 for the resistor R will be described below.

In FIG. 1F, three contact plugs 15 are formed on one silicide region 14, the other silicide region 14, and the electrode material layer 9. The contact plugs 15 are used to control the lower electrode layer (the substrate 1), the intermediate electrode layer (the semiconductor layer 5), and the upper electrode layer (the electrode material ground layer 8 and the electrode material layer 9) of the capacitor C.

Hereinafter, more details of the semiconductor device according to the embodiment will be described continuously with reference to FIGS. 1A to 1F.

In FIGS. 1A to 1D, channel lengths of the transistors HV(N) and HV(P) are substantially the same as channel lengths of the transistors LV(N) and LV(P). However, the channel lengths of the transistors HV(N) and HV(P) may be longer than the channel lengths of the transistors LV(N) and LV(P).

In FIGS. 1A to 1D, gate length directions of the transistors HV(N), HV(P), LV(N), and LV(P) are parallel to the X direction. However, the gate length directions of the transistors HV(N), HV(P), LV(N), and LV(P) may not be parallel to the X direction or may be parallel to, for example, the Y direction. Similarly, a cross section illustrated in FIG. 1E or a cross section illustrated in FIG. 1F may be surfaces other than XZ cross sections and may be, for example, YZ cross sections.

The capacitor C according to the embodiment includes a lower capacitor formed between the lower electrode layer (the substrate 1) and the intermediate electrode layer (the semiconductor layer 5) and an upper capacitor formed between the intermediate electrode layer (the semiconductor layer 5) and the upper electrode layer (the electrode material ground layer 8 and the electrode material layer 9). According to the embodiment, the capacitor C includes the lower capacitor and the upper capacitor stacked in the Z direction. Thus, capacitance of the capacitor C can increase although an area of the capacitor C does not increase in a plan view.

The resistor R according to the embodiment includes conductive layers (the electrode material ground layer 8 and the electrode material layer 9) formed above the upper surface of the element isolation area 2, and the upper surface of the element isolation area 2 is formed at a high location. The smaller a cross section area of a longitudinal cross section (XZ cross section) of the conductive layers is, the larger a value of the resistor R is. The thinner the thickness of the conductive layers is, the smaller the cross section area is. Accordingly, according to the embodiment, by raising the above-described upper surface of the element isolation area 2, it is possible to make the thickness of the conductive layers thin, and thus it is possible to increase the value of the resistor R. A width of the conductive layers of the resistor R in the X direction may be less or greater than a width of the gate electrodes (the electrode material ground layer 8 and the electrode material layer 9) of the transistors LV(N) and LV(P) in the X direction.

The electrode material ground layer 8 and the electrode material layer 9 according to the embodiment are used as the gate electrodes of the transistors HV(N), HV(P), LV(N), and LV(P), are used as the conductive layers of the resistor R, and are used as the upper electrode layer of the capacitor C. According to the embodiment, the gate electrodes of the transistors HV(N), HV(P), LV(N), and LV(P), the conductive layers of the resistor R, and the upper electrode layer of the capacitor C can be formed simply using a common material such as the electrode material ground layer 8 and the electrode material layer 9. In the embodiment, other elements of the transistors HV(N), HV(P), LV(N), and LV(P), the resistor R, and the capacitor C are also formed using the common material, as described above.

The semiconductor device according to the embodiment includes the high-voltage transistors (the transistors HV(N) and HV(P)) as well as the low-voltage transistors (the transistors LV(N) and LV(P)). According to the embodiment, for example, a circuit in which a high breakdown voltage is necessary can also be formed using the high-voltage transistors. The semiconductor device according to the embodiment may include only one type, two types, or three types of transistors among the four types of transistors HV(N), HV(P), LV(N), and LV(P).

The semiconductor device according to the embodiment is, for example, a semiconductor memory. In this case, the transistors HV(N), HV(P), LV(N), and LV(P), the resistor R, and the capacitor C are used in, for example, a circuit controlling a memory cell array in the semiconductor memory. An example of the circuit is a voltage generation circuit to be described below. The example of the semiconductor device will be described in detail in second and third embodiments to be described below.

The semiconductor device according to the embodiment may be a device other than the semiconductor memory. In this case, the transistors HV(N), HV(P), LV(N), and LV(P), the resistor R, and the capacitor C are used in, for example, a digital-analog mixed circuit. According to the embodiment, by applying the structure of the embodiment to a digital-analog mixed circuit, for example, it is possible to appropriately form the digital-analog circuit in which a high breakdown voltage is necessary.

The capacitor C according to the embodiment is formed in a form in which the substrate 1 is used as the lower electrode layer. That is, the capacitor C according to the embodiment is formed not at a location away from the upper surface of the substrate 1 but at a location in contact with the upper surface of the substrate 1, and the substrate 1 becomes a part of the capacitor C according to the embodiment. Accordingly, for example, it is possible to appropriately handle a high voltage with the capacitor C. A charge pump is a circuit that generates a high voltage. Since a high voltage is handled frequently, the capacitor C according to the embodiment is appropriate for a charge pump. In general, since the charge pump is formed using not only a low-voltage transistor but also a high-voltage transistor, the structure according to the embodiment is appropriate for the charge pump from the viewpoint of a high breakdown voltage.

The capacitor C is formed to be in contact with the side surface and the upper surface of the element isolation area 2 in FIG. 1F, but may be formed to be in contact with only the side surface or the upper surface of the element isolation area 2 or may be formed not to be in contact with the element isolation area 2.

The lower surface of the insulating film 7 below the resistor R is in contact with only the upper surface of the element isolation area 2 in FIG. 1E, but may be in contact with the upper surface of the element isolation area 2 and the upper surface of the substrate 1. That is, the insulating film 7 below the resistor R may be formed to protrude on the upper surface of the substrate 1. Similarly, the electrode material ground layer 8 or the electrode material layer 9 in the resistor R may be formed to protrude on the upper surface of the substrate 1.

The transistors HV(N), HV(P), LV(N), and LV(P) are planar field effect transistors (FETs) in FIGS. 1A to 1D, but may be other type transistors. For example, the transistors HV(N), HV(P), LV(N), and LV(P) may be fin type FETs or trench type FETs.

As described above, according to the embodiment, when devices such as the transistors HV(N), HV(P), LV(N), and LV(P), the resistor R, and the capacitor C are formed on the substrate 1, the devices that have appropriate performance can be formed.

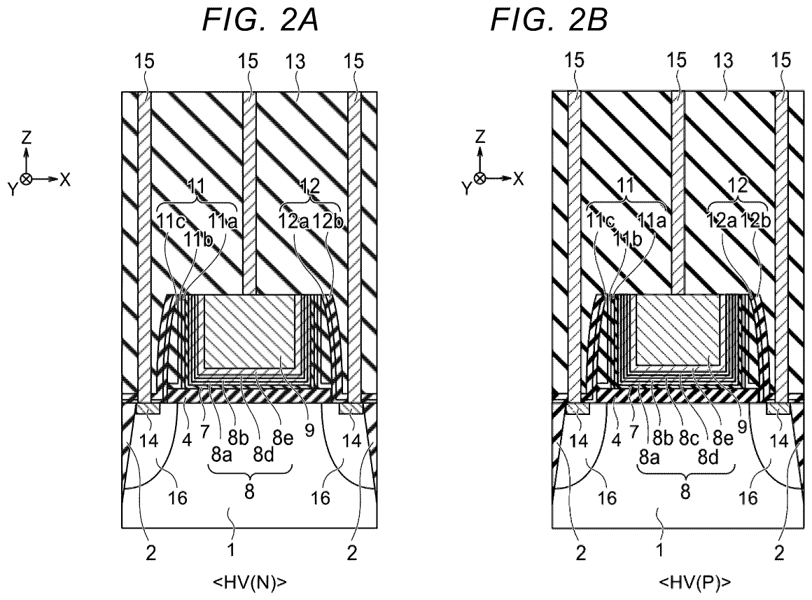

FIGS. 2A to 4B are sectional views illustrating details of the structure of the semiconductor device according to the first embodiment.

FIG. 2A is an enlarged diagram illustrating the transistor HV(N) illustrated in FIG. 1A. The semiconductor device according to the embodiment includes source/drain regions 16 formed in the substrate 1 such that the gate electrodes (the electrode material ground layer 8 and the electrode material layer 9) of the transistor HV(N) are interposed therebetween. FIG. 2A further illustrates the silicide regions 14 formed in the source/drain regions 16.

In FIG. 2A, the electrode material ground layer 8 includes four metal layers 8a, 8b, 8d, and Be formed in order on the upper surface and the side surface of the insulating film 7. The metal layer 8a is, for example, a titanium nitride film (TiN film). The metal layer 8b is, for example, a tantalum nitride film (TaN film). The metal layer 8d is, for example, a titanium aluminum film (TiAl film). The metal layer 8e is, for example, a TiN film. In the embodiment, the metal layers 8a and 8b are provided to make a work function of the electrode material ground layer 8 appropriate, the metal layer 8d is provided as an electrode layer, and the metal layer 8e is provided as a barrier metal layer.

In FIG. 2A, the side wall insulating film 11 includes an insulating film 11a formed on a side surface of the insulating film 7, an insulating film 11b formed on a side surface of the insulating film 11a and an upper surface of the insulating film 4, and an insulating film 11c formed on a side surface and an upper surface of the insulating film 11b. The insulating film 11a is, for example, a SiO₂ film. The insulating film 11b is, for example, a silicon nitride film (SiN film). The insulating film 11c is, for example, a SiO₂ film.

In FIG. 2A, the liner insulating film 12 includes an insulating film 12a formed on a side surface of the insulating film 11c and upper surface or the like of the substrate 1 and the element isolation area 2, and an insulating film 12b formed on a side surface and an upper surface of the insulating film 12a. The insulating film 12a is, for example, a SiO₂ film. The insulating film 12b is, for example, a SiN film. The contact plug 15 on each silicide region 14 is formed to penetrate through the liner insulating film 12.

FIG. 2B is an enlarged diagram illustrating the transistor HV(P) illustrated in FIG. 1B. The semiconductor device according to the embodiment includes source/drain regions 16 formed in the substrate 1 such that the gate electrodes (the electrode material ground layer 8 and the electrode material layer 9) of the transistor HV(P) are interposed therebetween. FIG. 2B further illustrates the silicide regions 14 formed in the source/drain regions 16.

In FIG. 2B, the electrode material ground layer 8 includes a metal layer 8c formed between the metal layers 8b and 8d in addition to the metal layers 8a, 8b, 8d, and 8e. The metal layer 8c is, for example, a TiN film. In the embodiment, the metal layer 8c is provided to make a work function of the electrode material ground layer 8 appropriate.

In FIG. 2B, the side wall insulating film 11 and the liner insulating film 12 are formed similarly to FIG. 2A.

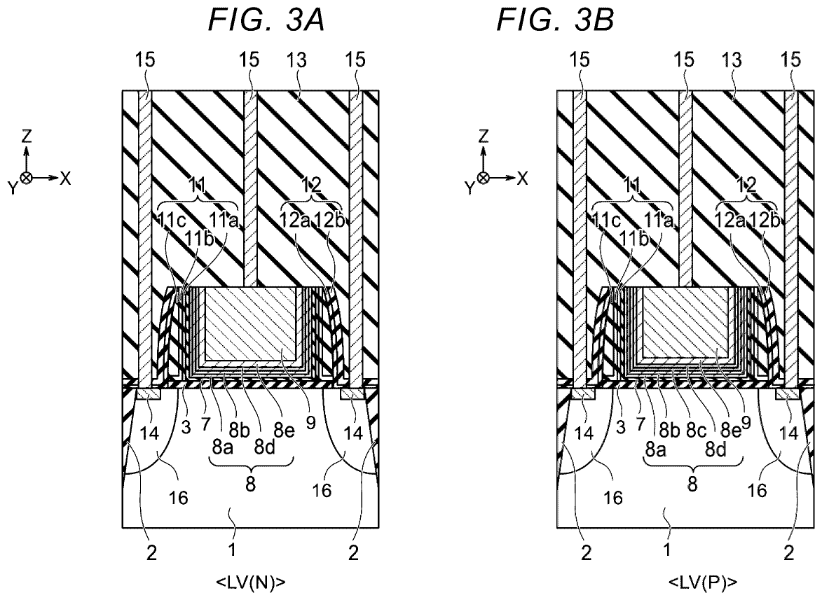

FIG. 3A is an enlarged diagram illustrating the transistor LV(N) illustrated in FIG. 1C. The semiconductor device according to the embodiment includes source/drain regions 16 formed in the substrate 1 such that the gate electrodes (the electrode material ground layer 8 and the electrode material layer 9) of the transistor LV(N) are interposed therebetween. FIG. 3A further illustrates the silicide regions 14 formed in the source/drain regions 16.

In FIG. 3A, the electrode material ground layer 8 or the side wall insulating film 11 and the liner insulating film 12 are formed similarly to FIG. 2A. Here, the insulating film 11b is formed on a side surface of the insulating film 11a and an upper surface of the insulating film 3.

FIG. 3B is an enlarged diagram illustrating the transistor LV(P) illustrated in FIG. 1D. The semiconductor device according to the embodiment includes source/drain regions 16 formed in the substrate 1 such that the gate electrodes (the electrode material ground layer 8 and the electrode material layer 9) of the transistor LV(P) are interposed therebetween. FIG. 3B further illustrates the silicide regions 14 formed in the source/drain regions 16.

In FIG. 3B, the electrode material ground layer 8 or the side wall insulating film 11 and the liner insulating film 12 are formed similarly to FIG. 2B. Here, the insulating film 11b is formed on a side surface of the insulating film 11a and an upper surface of the insulating film 3.

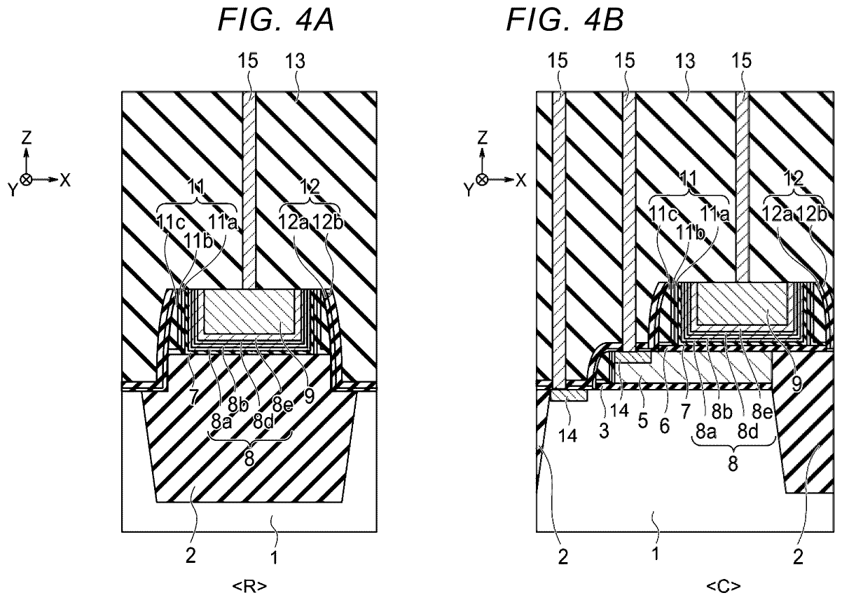

FIG. 4A is an enlarged diagram illustrating the resistor R illustrated in FIG. 1E.

In FIG. 4A, the electrode material ground layer 8 or the side wall insulating film 11 and the liner insulating film 12 are formed similarly to FIG. 2A. Here, the insulating film 11b is formed on a side surface of the insulating film 11a and an upper surface of the element isolation area 2, and the insulating film 12a is formed on side surfaces of the insulating film 11c and the element isolation area 2 and upper surfaces of the element isolation area 2 and the substrate 1. The electrode material ground layer 8 illustrated in FIG. 4A may further include the metal layer 8c.

FIG. 4B is an enlarged diagram illustrating the capacitor C illustrated in FIG. 1F.

In FIG. 4B, the electrode material ground layer 8 or the side wall insulating film 11 and the liner insulating film 12 are formed similarly to FIG. 2A. Here, the insulating film 11b is formed on a side surface of the insulating film 11a and an upper surface of the insulating films 3 and 6, and the insulating film 12a is formed on a side surface of the insulating film 11c and upper surfaces of the semiconductor layer 5, the element isolation area 2, and the substrate 1. The electrode material ground layer 8 illustrated in FIG. 4B may further include the metal layer 8c.

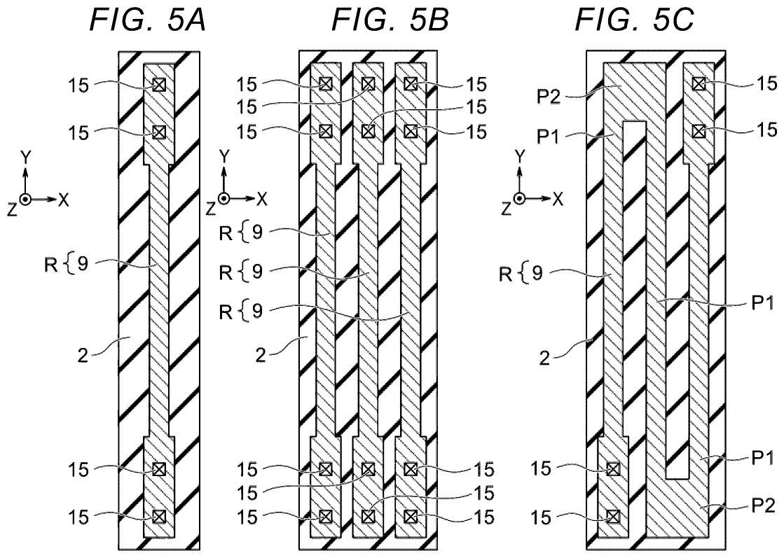

FIGS. 5A to 5C are plan views illustrating three examples of the structure of the semiconductor device according to the first embodiment.

FIG. 5A illustrates a first example of the semiconductor device according to the embodiment. FIG. 5A illustrates a planar shape of the electrode material layer 9 in the resistor R and does not illustrate the electrode material ground layer 8 or the like formed on the side surface of the electrode material layer 9. In FIG. 5A, the electrode material layer 9 extends in the Y direction on the element isolation area 2.

FIG. 5A further illustrates four contact plugs 15 formed on the electrode material layer 9. As the contact plugs 15, two contact plugs 15 (hereinafter referred to as “first contact plugs 15”) disposed in the vicinity of an end of the electrode material layer 9 in the +Y direction and two contact plugs 15 (hereinafter referred to as “second contact plugs 15”) disposed in the vicinity of an end of the electrode material layer 9 in the −Y direction. In FIG. 5A, the electrode material layer 9 (and the electrode material ground layer 8) between the first contact plugs 15 and the second contact plugs 15 functions as the resistor R.

FIG. 5B illustrates a second example of the semiconductor device according to the embodiment. In FIG. 5B, the plurality of resistors R (the electrode material layer 9) are disposed on one element isolation area 2. The resistors R are adjacent to each other in the X direction. The structure of each resistor R illustrated in FIG. 5B is the same as the structure of the resistor R illustrated in FIG. 5A.

The semiconductor device according to the embodiment may include many resistors R on one element isolation area 2 similarly to the case of FIG. 5B. In this case, several electrode material layers 9 in the vicinities of the ends in the #X direction among the resistors R may not be used as the resistors R. This is because the electrode material layers 9 in the vicinities of the ends in the +X direction often do not have a stable shape.

FIG. 5C illustrates a third example of the semiconductor device according to the embodiment. In FIG. 5C, one resistor R (the electrode material layer 9) extends in a meandering form above one element isolation area 2. Specifically, the electrode material layer 9 includes three portions P1 extending in the Y direction and two portions P2 connecting the portions P1 to each other. Accordingly, the length of the electrode material layer 9 between the first contact plug 15 and the second contact plug 15 can be increased, which can increase the resistor R. The number of portions P1 may be N and the number of portions P2 may be N−1 (where N is an integer of 2 or more).

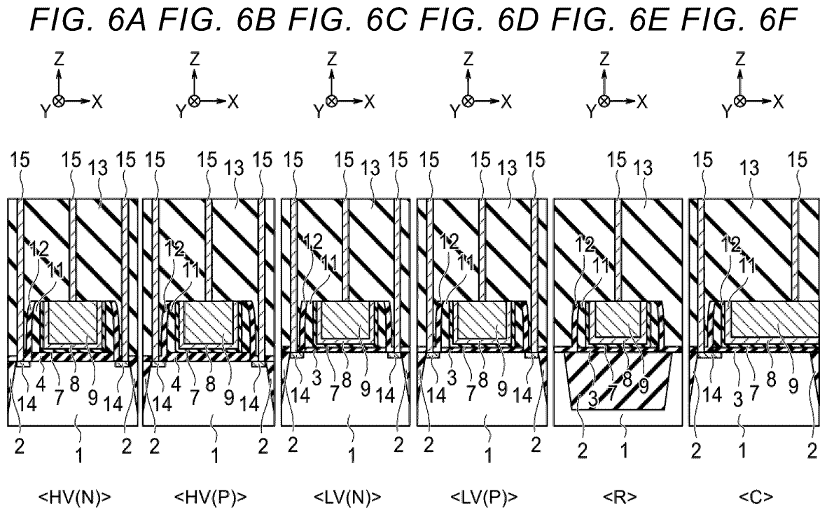

FIGS. 6A to 6F are sectional views illustrating a structure of a semiconductor device according to a comparative example of the first embodiment.

FIGS. 6A to 6F correspond to FIGS. 1A to 1F, respectively. The structures of FIGS. 6A to 6F are similar to the structures of FIGS. 1A to 1F, respectively. Here, a height of the upper surface of the element isolation area 2 illustrated in FIG. 6E is the same as a height of the upper surface of the substrate 1 illustrated in FIG. 6E. Further, the capacitor C illustrated in FIG. 6F does not include the semiconductor layer 5 and the insulating film 6, and thus includes only one capacitor between the lower electrode layer (the substrate 1) and the upper electrode layer (the electrode material ground layer 8 and the electrode material layer 9).

In the comparative example, the capacitor C includes one capacitor between the lower and upper electrode layers. Therefore, in the comparative example, without increasing an area of the capacitor C in a plan view, it is difficult to increase capacitance of the capacitor C. In the embodiment, however, the capacitor C includes lower and upper capacitors stacked in the Z direction. Accordingly, according to the embodiment, the capacitance of the capacitor C can be increased without increasing the area of the capacitor C in a plan view. The resistor R according to the comparative example includes the electrode material ground layer 8 and the electrode material layer 9 formed on the upper surface of the element isolation area 2, and the upper surface of the element isolation area 2 is formed at a low location. Therefore, in the comparative example, the thickness of the conductive layer in the resistor R becomes thick, and a value of the resistor R may decrease. However, the resistor R according to the embodiment includes the electrode material ground layer 8 and the electrode material layer 9 formed above the upper surface of the element isolation area 2, and the upper surface of the element isolation area 2 is formed at a high location. Accordingly, according to the embodiment, the thickness of the conductive layer in the resistor R can become thin, and the value of the resistor R can increase.

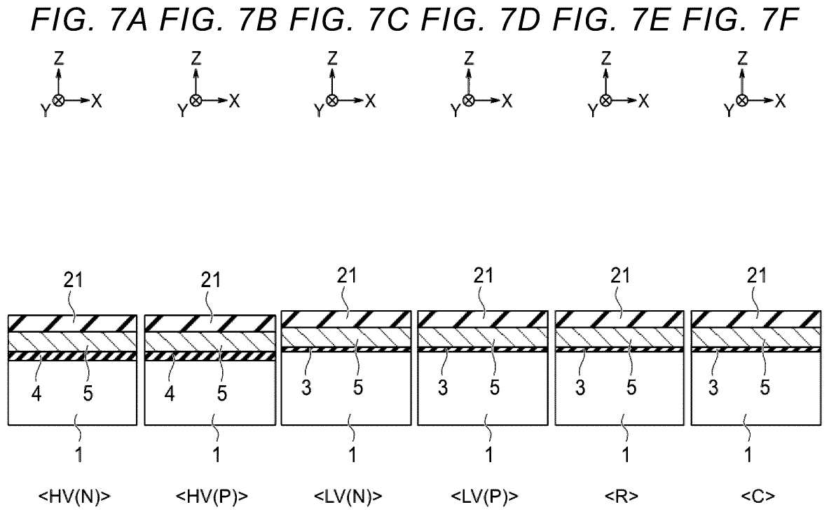

FIGS. 7A to 25F are sectional views illustrating a method of manufacturing the semiconductor device according to the first embodiment.

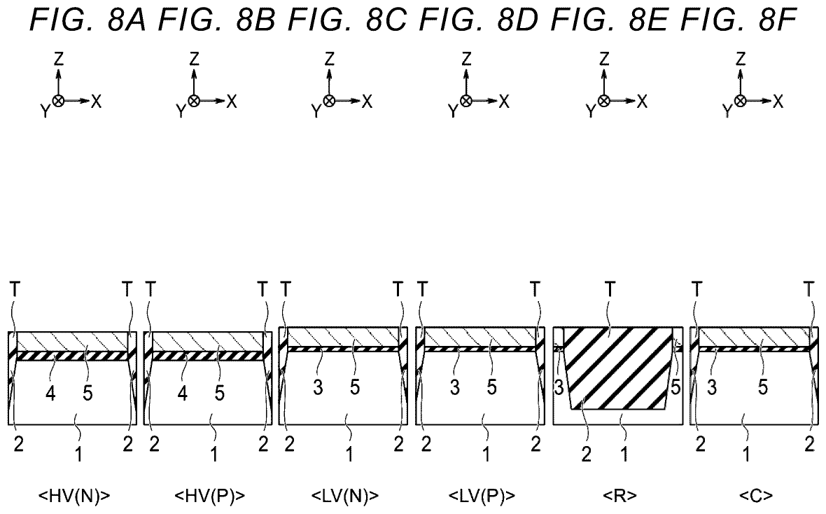

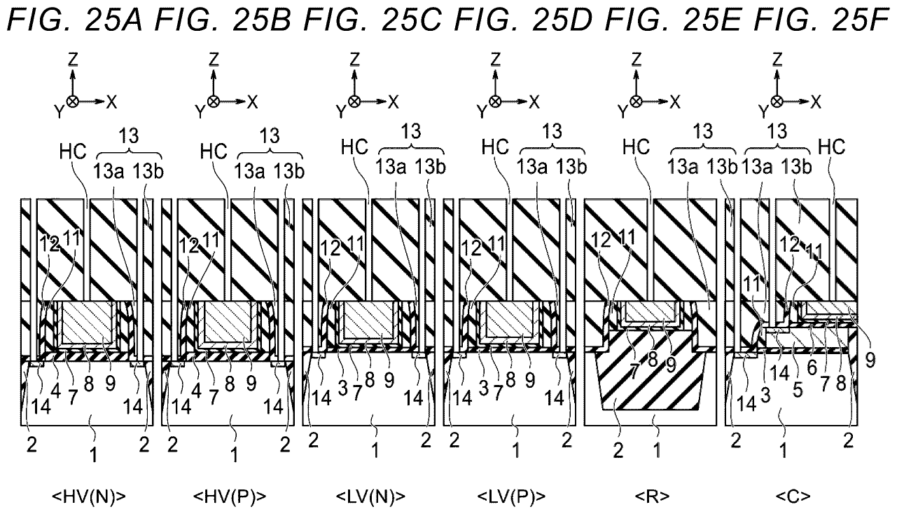

FIGS. 7A to 7F, FIGS. 8A to 8F, . . . , and FIGS. 25A to 25F correspond to FIGS. 1A to 1F, respectively. Hereinafter, processes of manufacturing the semiconductor device illustrated in FIGS. 1A to 1F will be described.

First, a part of the substrate 1 is processed from the upper surface of the substrate 1 by lithography and etching (FIGS. 7A to 7F). As a result, the upper surface of the substrate 1 illustrated in FIGS. 1A and 1B is lower than the upper surface of the substrate 1 illustrated in FIGS. 1C to 1F. Subsequently, the insulating film 4 is formed on the upper surface of the substrate 1 illustrated in FIGS. 1A and 1B and the insulating film 3 is formed on the upper surface of the substrate 1 illustrated in FIGS. 1C to 1F (FIGS. 7A to 7F). In the embodiment, the thickness of the insulating film 4 is set to be higher than the thickness of the insulating film 3.

Subsequently, the semiconductor layer 5 is formed on the insulating films 3 and 4 and a cap layer 21 is formed on the semiconductor layer 5 (FIGS. 7A to 7F). The semiconductor layer 5 is, for example, a polysilicon layer containing boron (B) atoms, phosphorus (P) atoms, or arsenic (As) atoms as impurity atoms. The semiconductor layer 5 containing B atoms is formed, for example, by forming a semiconductor layer containing no B atoms and subsequently implanting B atoms into the semiconductor layer. The semiconductor layer 5 containing P atoms is formed, for example, by a semiconductor layer containing P atoms from the first time. The same applies to the semiconductor layer 5 containing As atoms. Meanwhile, the semiconductor layer 5 containing P atoms or As atoms may be formed by a scheme similar to that of the semiconductor layer 5 containing B atoms. The cap layer 21 is, for example, a SiN film.

Subsequently, the trench T is formed in the cap layer 21, the semiconductor layer 5, the insulating film 4, the insulating film 3, and the substrate 1 by lithography and reactive ion etching (RIE), an insulating film (for example, a SiO₂ film) is formed in the trench T, and the surface of the insulating film is flattened by CMP (FIGS. 8A to 8F). As a result, the plurality of element isolation areas 2 are formed in the trench T, that is, the substrate 1, the insulating film 3, the insulating film 4, the semiconductor layer 5, and the cap layer 21.

Subsequently, a part of the element isolation area 2 is processed from the upper surface of the element isolation area 2 by etchback (FIGS. 8A to 8F). As a result, the upper surface of the element isolation area 2 is lowered. Subsequently, the cap layer 21 is removed (FIGS. 8A to 8F). The etchback in the embodiment is performed until the height of the upper surface of the element isolation area 2 becomes substantially the same as the height of the upper surface of the semiconductor layer 5.

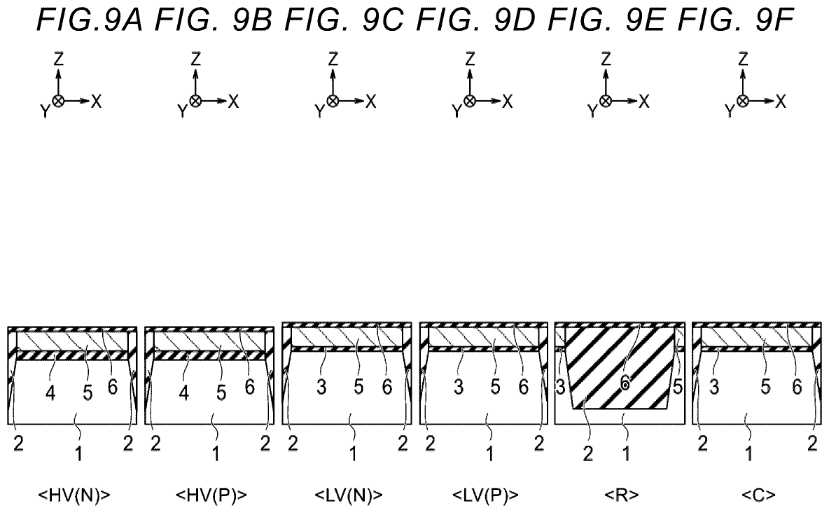

Subsequently, the insulating film 6 is formed on the semiconductor layer 5 and the element isolation area 2 (FIGS. 9A to 9F). The insulating film 6 is an example of a first portion of the second dielectric layer.

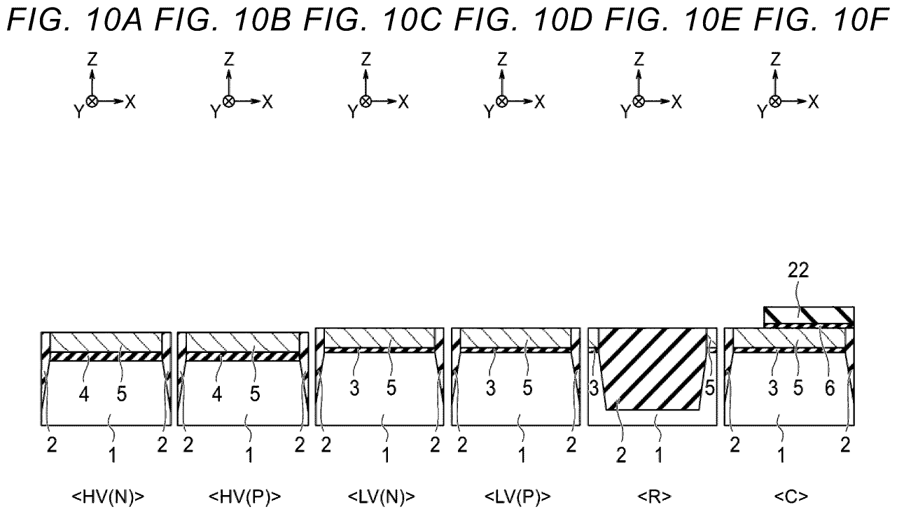

Subsequently, a resist layer 22 is formed on the insulating film 6, the resist layer 22 is patterned, and the insulating film 6 is processed by etching using the resist layer 22 (FIGS. 10A to 10F). As a result, the insulating film 6 is removed from regions illustrated in FIGS. 10A to 10E, and thus the semiconductor layer 5 becomes exposed. The insulating film 6 illustrated in FIG. 10F is processed in a predetermined shape.

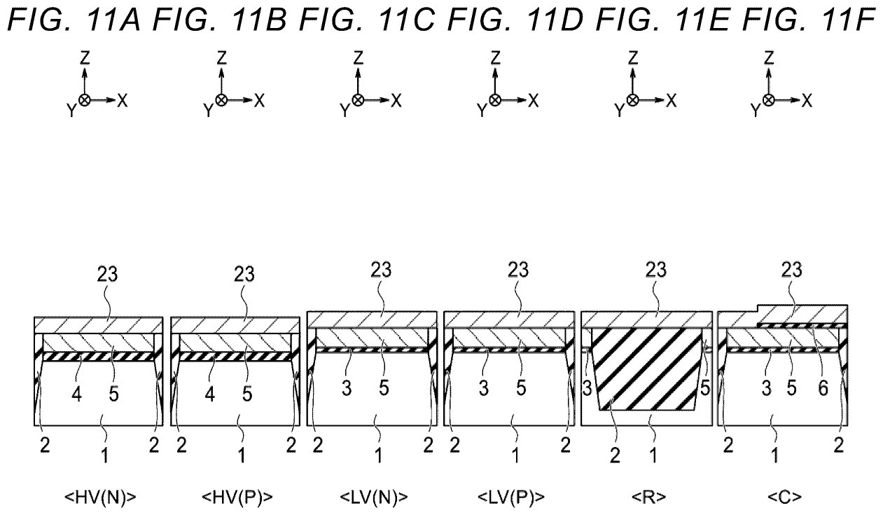

Subsequently, a semiconductor layer 23 is formed on the semiconductor layer 5 and the insulating film 6 (FIGS. 11A to 11F). The semiconductor layer 23 is, for example, a polysilicon layer (undoped polysilicon film) that does not substantially contain impurity atoms such as B atoms, P atoms, or As atoms. The semiconductor layer 23 is an example of a first layer.

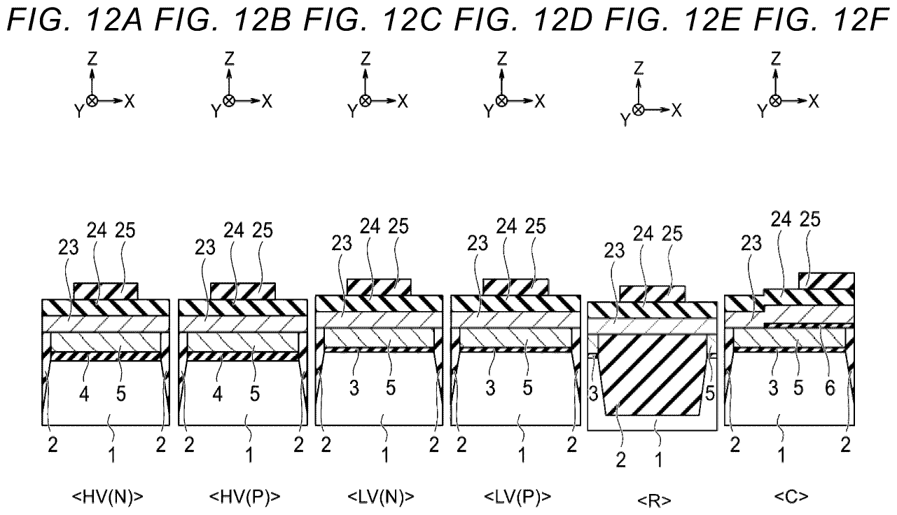

Subsequently, a cap layer 24 is formed on the semiconductor layer 23, a resist layer 25 is formed on the cap layer 24, and the resist layer 25 is patterned (FIGS. 12a to 12F). As a result, a plurality of patterns of the resist layer 25 are formed in regions illustrated in FIGS. 12A to 12F. The patterns are used to form a plurality of recess portions for burying the insulating film 7, the electrode material ground layer 8, and the electrode material layer 9, as will be described below. The cap layer 24 is, for example, a SiN film. The cap layer 24 is also an example of the first layer.

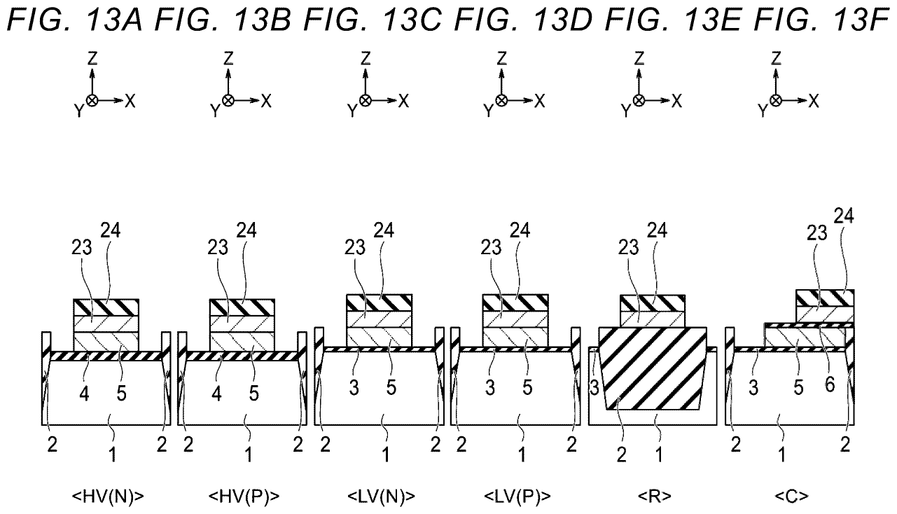

Subsequently, the cap layer 24, the semiconductor layer 23, and the semiconductor layer 5 are processed by RIE using the resist layer 25, and the resist layer 25 is subsequently removed (FIGS. 13A to 13F). As a result, the patterns of the resist layer 25 are transferred to the cap layer 24, the semiconductor layer 23, and the semiconductor layer 5 in regions illustrated in FIGS. 13A to 13E, and are transferred to the cap layer 24 and the semiconductor layer 23 in a region illustrated in FIG. 13F. Further, a shape of the insulating film 6 is transferred to the semiconductor layer 5 in the region illustrated in FIG. 13F.

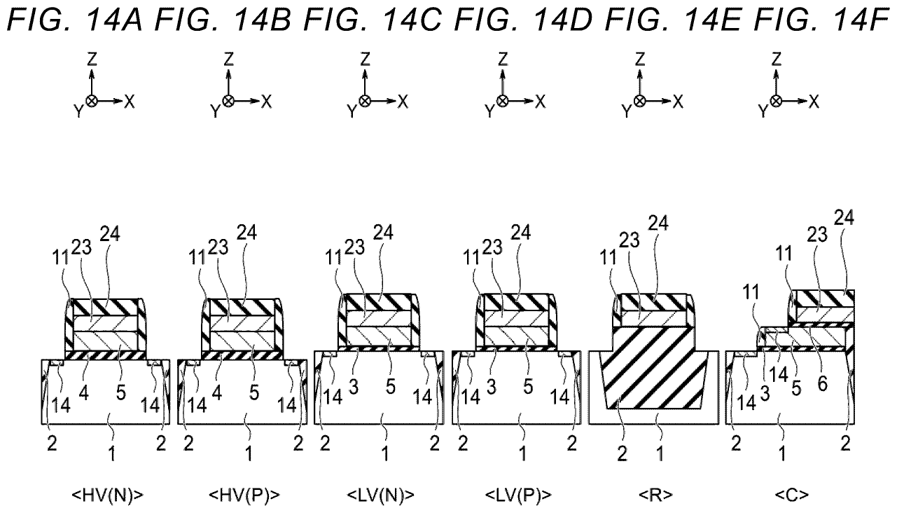

Subsequently, the side wall insulating film 11 is formed on the entire surface of the substrate 1 and the side wall insulating film 11 is processed by etchback (FIGS. 14A to 14F). Through the etchback, the side wall insulating film 11 remains on the side surfaces of the cap layer 24, the semiconductor layer 23, and the semiconductor layer 5 and is removed from the other regions. As a result, portions of the upper surfaces of the substrate 1, the element isolation area 2, the semiconductor layer 5, and the cap layer 25 are exposed. Through the etchback, the element isolation area 2 exposed from the side wall insulating film 11 is processed, and thus the upper surface of the processed portion of the element isolation area 2 is lowered. In the embodiment, the upper surface of the processed portion of the element isolation area 2 is lowered to the upper surface of the substrate 1.

Subsequently, the plurality of silicide regions 14 are formed in the substrate 1 and the semiconductor layer 5 (FIGS. 14A to 14F). The silicide regions 14 are formed in portions exposed by the etchback in the substrate 1 and the semiconductor layer 5. In the processes illustrated in FIGS. 14A to 14F, the process of forming the silicide regions 14 may be omitted.

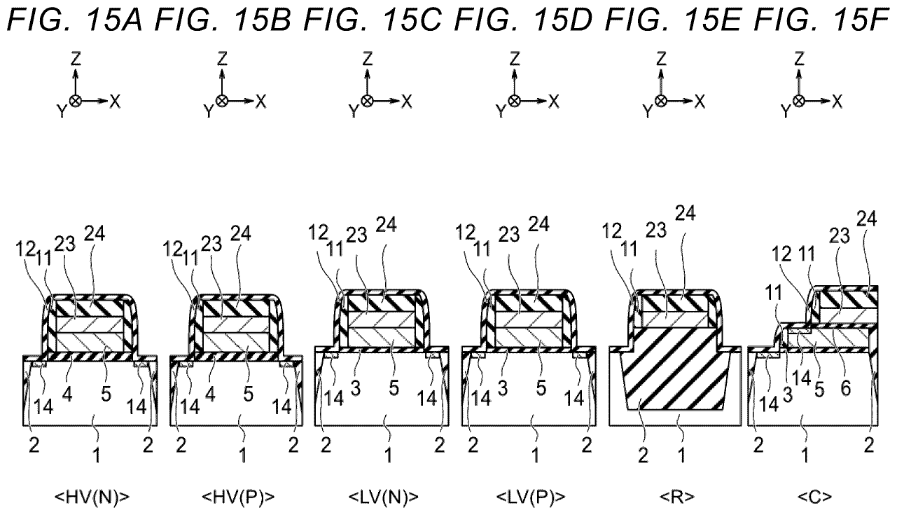

Subsequently, the liner insulating film 12 is formed on the entire surface of the substrate 1 (FIGS. 15A to 15F). As a result, the liner insulating film 12 is formed on the surfaces of the substrate 1, the element isolation area 2, the semiconductor layer 5, the side wall insulating film 11, and the cap layer 24.

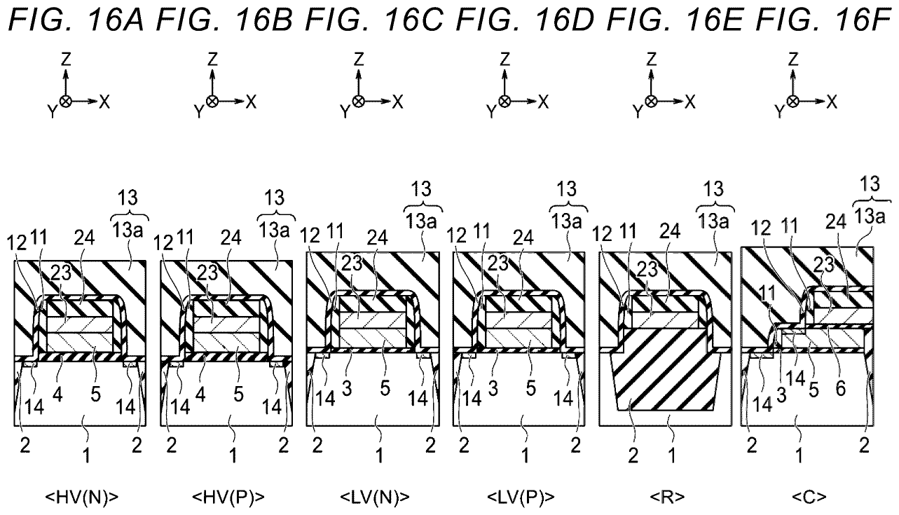

Subsequently, an insulating film 13a that is a part of the interlayer insulating film 13 is formed on the entire surface of the substrate 1 (FIGS. 16A to 16F). As a result, the liner insulating film 12 or the like is covered with the insulating film 13a. The insulating film 13a is, for example, a SiO₂ film.

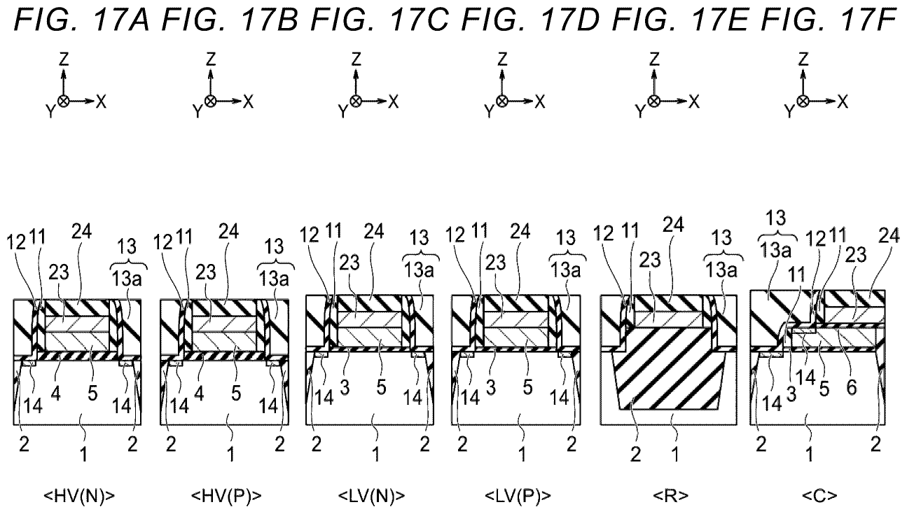

Subsequently, the surface of the insulating film 13a is flattened (FIGS. 17A to 17F). As a result, the insulating film 13a and the liner insulating film 12 are removed from the upper surface of the cap layer 24 to expose the upper surface of the cap layer 24. The surface of the insulating film 13a is flattened by, for example, CMP. In this way, insulating films such as the side wall insulating film 11, the liner insulating film 12, and the insulating film 13a are formed on side surfaces of the cap layer 24, the semiconductor layer 23, the semiconductor layer 5, and the like.

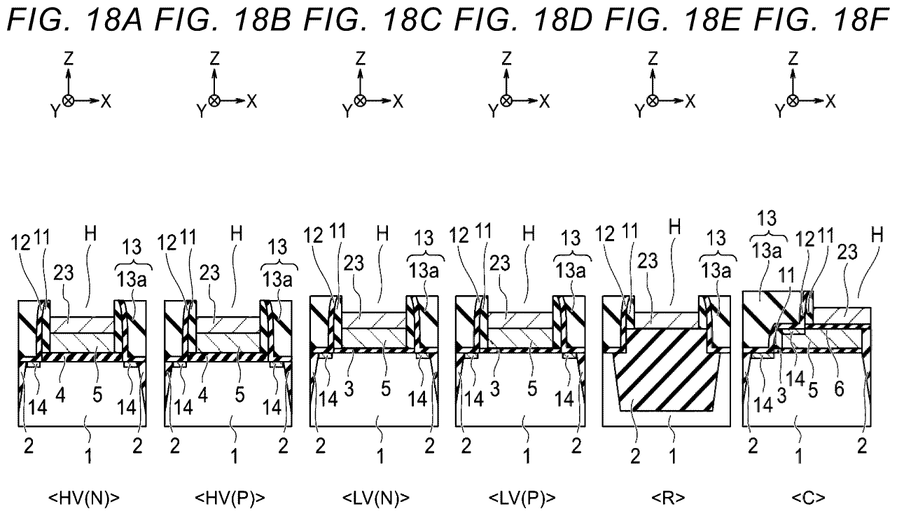

Subsequently, the cap layer 24 is removed (FIGS. 18A to 18F). As a result, a plurality of recess portions H illustrated in FIGS. 18A to 18F are formed. Each recess portion H is formed on the semiconductor layer 23 in the insulating films including the side wall insulating film 11, the liner insulating film 12, and the insulating film 13a, and the upper surface of the semiconductor layer 23 is exposed in the recess portion H.

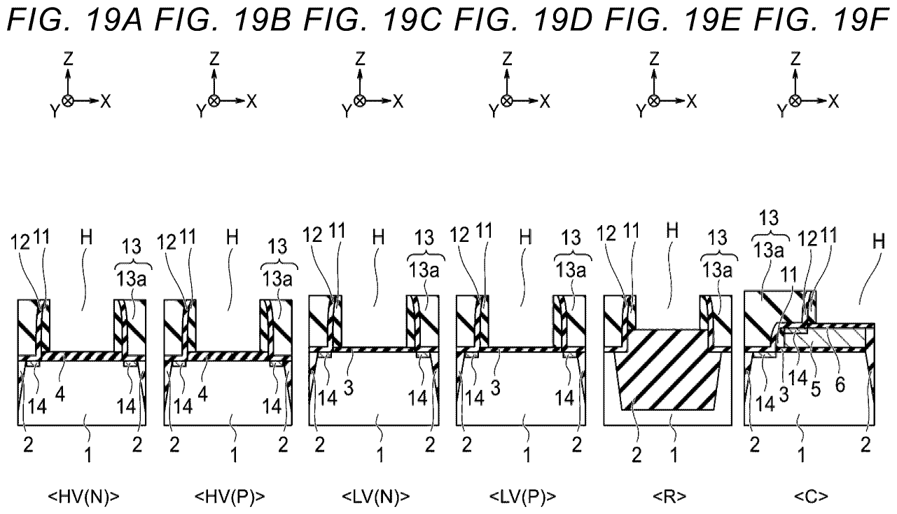

Subsequently, the semiconductor layers 23 and 5 are removed in the recess portions H (FIGS. 19A to 19F). As a result, in each recess portion H illustrated in FIGS. 19A to 19F, the side surface of the side wall insulating film 11 and the upper surface of the insulating film 4, the insulating film 3, the element isolation area 2, or the insulating film 6 are exposed. The semiconductor layer 5 illustrated in FIG. 19F is not removed since the semiconductor layer 5 is covered with the insulating film 6.

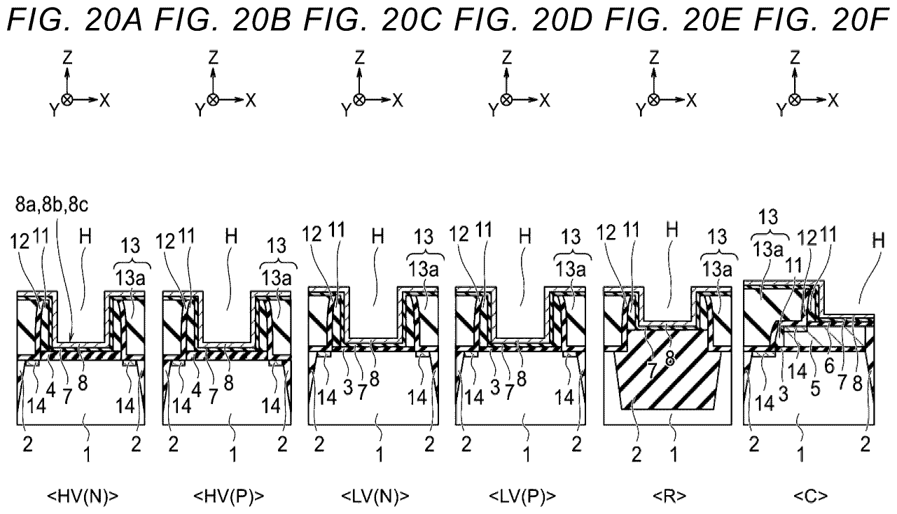

Subsequently, the insulating film 7 and the metal layers 8a, 8b, and 8c of the electrode material ground layer 8 are formed in order on the entire surface of the substrate 1 (FIGS. 20A to 20F). As a result, the insulating film 7 and the metal layers 8a, 8b, and 8c are formed in each recess portion H to cover the side surface and the bottom surface of each recess portion H. The insulating film 7 is an example of a second portion of the second dielectric layer. Each side surface of each recess portion H is formed on the side wall insulating film 11, and the bottom surface of each recess portion H is formed on the insulating film 4, the insulating film 3, the element isolation area 2, or the insulating film 6.

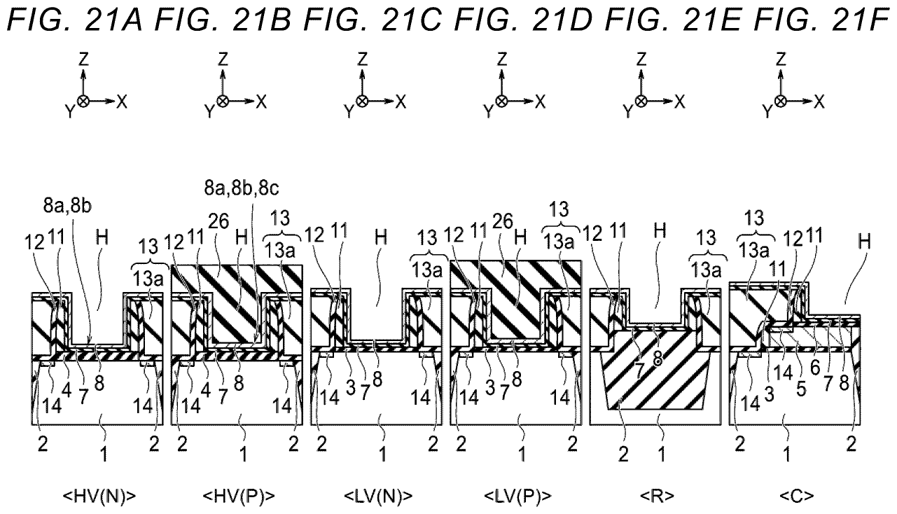

Subsequently, a resist layer 26 is formed on the metal layer 8c and the resist layer 26 is patterned (FIGS. 21A to 21F). As a result, regions illustrated in FIGS. 21B and 21D are covered with the resist layer 26. Subsequently, the metal layer 8c is removed from the regions illustrated in FIGS. 21A, 21C, 21E, and 21F (FIGS. 21A to 21F). Accordingly, as described with reference to FIGS. 2A to 4B, the metal layer 8c can be removed from the regions illustrated in FIGS. 21A, 21C, 21E, and 21F while making the metal layer 8c remain in the regions illustrated in FIGS. 21B and 21D. The metal layer 8c may not be removed from the regions illustrated in FIG. 21E or the region illustrated in FIG. 21F. After the process illustrated in FIGS. 21A to 21F, the resist layer 26 is removed.

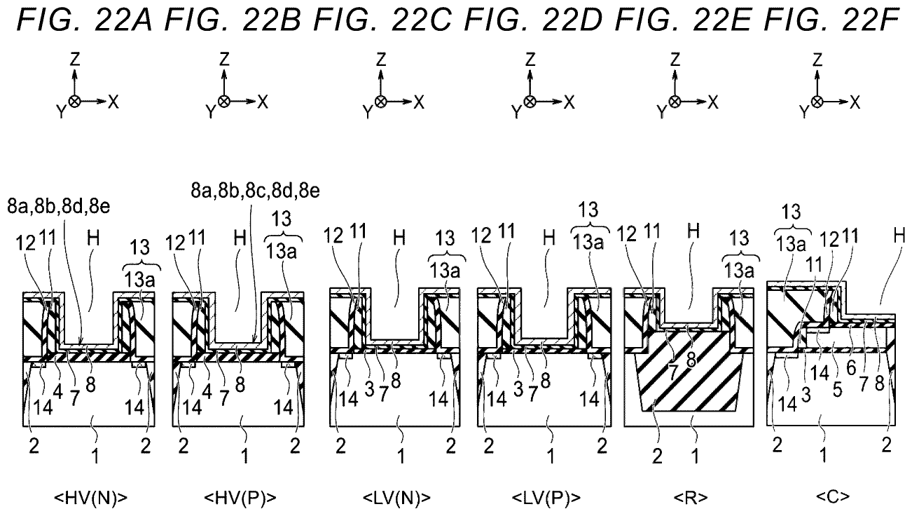

Subsequently, the metal layers 8d and 8e of the electrode material ground layer 8 are formed in order on the entire surface of the substrate 1 (FIGS. 22A to 22F). As a result, the metal layers 8d and 8e are formed in each recess portion H and covers the side surface and the bottom surface of each recess portion H. The metal layer 8d in the regions illustrated in FIGS. 22B and 22D is formed on the side surface and the upper surface of the metal layer 8c, and the metal layer 8d in the regions illustrated in FIGS. 22A, 22C, 22E, and 22F is formed on the side surface and the upper surface of the metal layer 8b.

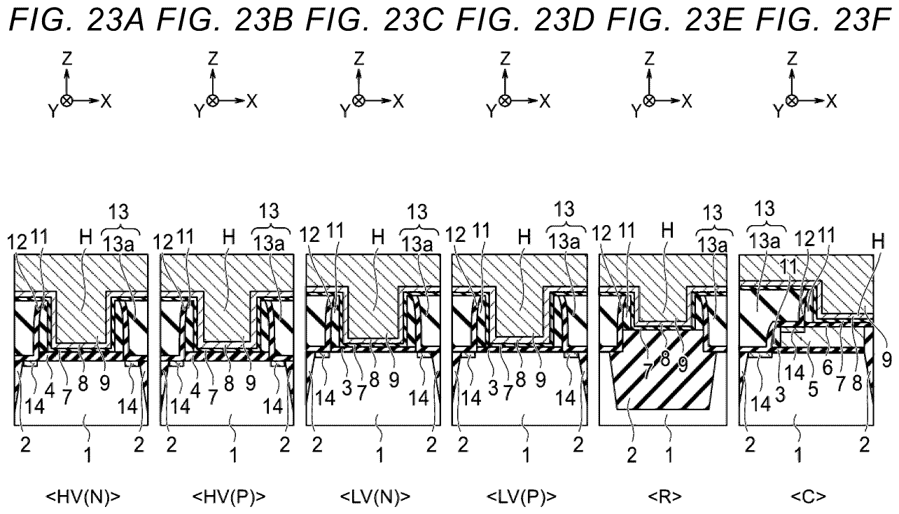

Subsequently, the electrode material layer 9 is formed on the entire surface of the substrate 1 (FIGS. 23A to 23F). As a result, the electrode material layer 9 is formed in each recess portion H. The electrode material layer 9 according to the embodiment is formed so that each recess portion H is filled with the electrode material layer 9.

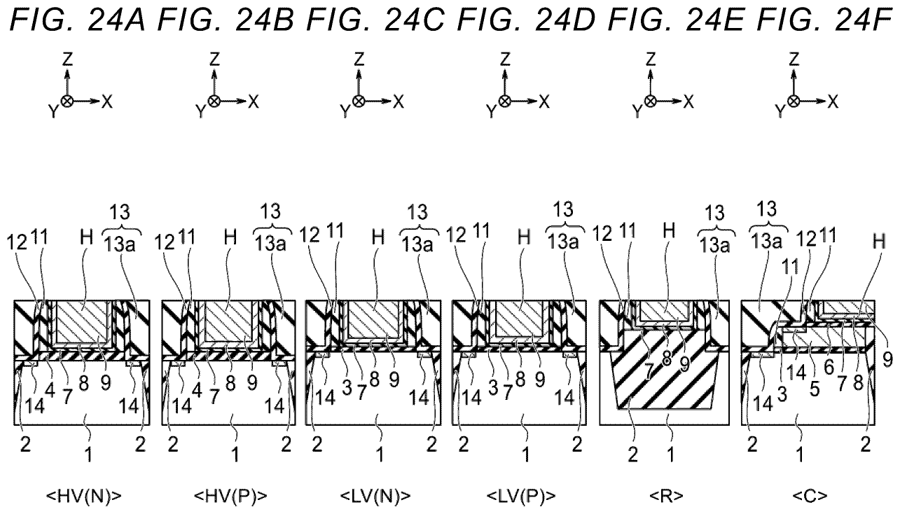

Subsequently, the surface of the electrode material layer 9 is flattened by CMP (FIGS. 24A to 24F). As a result, the electrode material layer 9, the electrode material ground layer 8, and the insulating film 7 outside of the plurality of recess portions H are removed, and thus the upper surfaces of the insulating film 13a, the liner insulating film 12, and the side wall insulating film 11 are exposed. In the embodiment, since the surface of the electrode material layer 9 is flattened by CMP, the height of the upper surface of the electrode material layer 9 illustrated in FIGS. 24A to 24F is substantially uniform. For example, the height of the upper surface of the electrode material layer 9 illustrated in FIG. 24A is substantially the same as the height of the upper surface of the electrode material layer 9 illustrated in each of FIGS. 24B to 24F.

Subsequently, an insulating film 13b that is another part of the interlayer insulating film 13 is formed on the entire surface of the substrate 1 (FIGS. 25A to 25F). As a result, the electrode material layer 9, the insulating film 13a, and the like are covered with the insulating film 13b. The insulating film 13b is, for example, a SiO₂ film.

Subsequently, a plurality of contact holes HC are formed in the interlayer insulating film 13 (FIGS. 25A to 25F). Each contact hole HC is formed to reach the upper surface of the silicide region 14 or the electrode material layer 9. Thereafter, the contact plug 15 is formed in each contact hole HC (See FIGS. 1A to 1F). When the process of forming the silicide region 14 is omitted in the processes illustrated in FIGS. 14A to 14F, the silicide region 14 may be formed in the substrate 1 and the semiconductor layer 5 from the contact hole HC in the processes illustrated in FIGS. 25A to 25F.

In this way, the semiconductor device according to the embodiment is manufactured. Specifically, the transistors HV(N), HV(P), LV(N), and LV(P), the resistor R, and the capacitor C are formed in the regions illustrated in FIGS. 25A to 25F.

Next, more details of the method of manufacturing the semiconductor device according to the embodiment will be described below with reference to FIGS. 7A to 25F.

The element isolation area 2 according to the embodiment is formed after the insulating film 3, the insulating film 4, the semiconductor layer 5, and the cap layer 21 are formed on the substrate 1 (FIGS. 8A to 8F). As a result, the height of the upper surface of the element isolation area 2 is higher than the height of the upper surface of the substrate 1. Accordingly, it is possible to make the conductive layers (the electrode material ground layer 8 and the electrode material layer 9) in the resistor R thin and it is possible to increase the value of the resistor R.

The gate electrodes of the transistors HV(N), HV(P), LV(N), and LV(P), the conductive layers of the resistor R, and the upper electrode layer of the capacitor C according to the embodiment are formed by burying the electrode material ground layer 8 and the electrode material layer 9 in the recess portions H (FIGS. 23A to 23F and the like). Accordingly, it is possible to form the gate electrodes, the conductive layers, and the upper electrode layer with an appropriate material such as a metal layers.

At this time, the recess portions H for the electrode material ground layer 8 and the electrode material layer 9 are formed while making the semiconductor layer 5 for the capacitor C remain (FIGS. 19A to 19F and the like). Accordingly, it is possible to form the capacitor C including the lower capacitor and the upper capacitor and it is possible to increase the capacitance of the capacitor C.

Next, various modified examples of the embodiment will be described.

### (1) First Modified Example

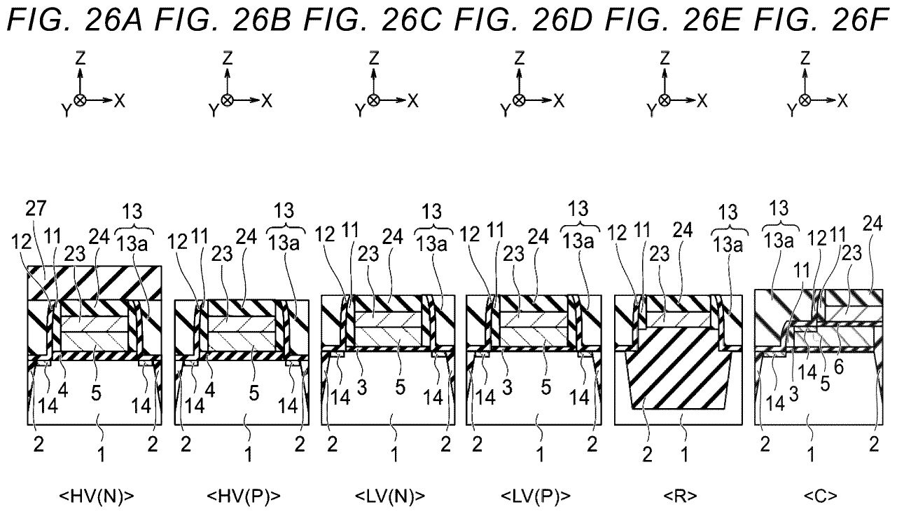

FIGS. 26A to 28F are sectional views illustrating a method of manufacturing a semiconductor device according to a first modified example of the first embodiment.

FIGS. 26A to 26F correspond to FIGS. 17A to 17F, respectively. In the modified example, after the processes illustrated in FIGS. 17A to 17F are performed, a resist layer 27 is formed on the entire surface of the substrate 1 and the resist layer 27 is patterned (FIGS. 26A to 26F). As a result, a region illustrated in FIG. 26A is covered with the resist layer 27.

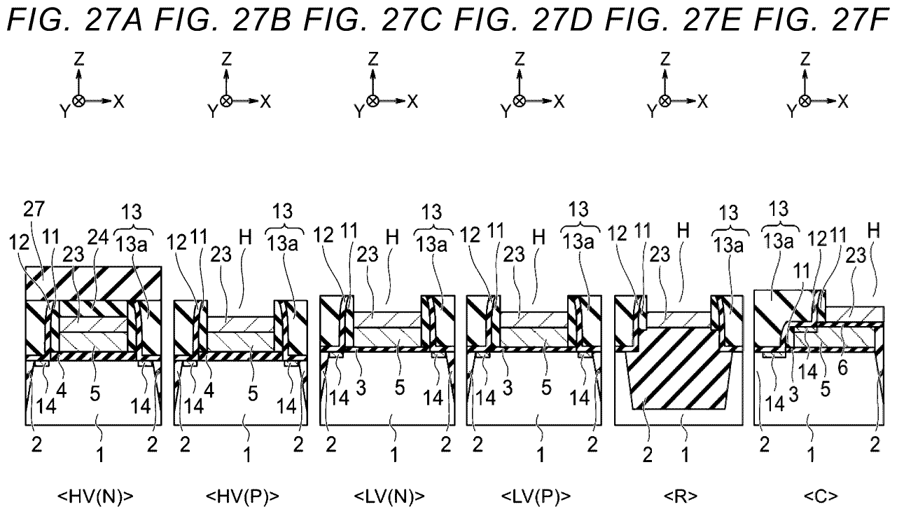

Subsequently, the cap layer 24 is removed (FIGS. 27A to 27F). Accordingly, it is possible to form the plurality of recess portions H illustrated in FIGS. 27B to 27F while making the cap layer 24 remain in the region illustrated in FIG. 27A. Each recess portion H is formed on the semiconductor layer 23 in the insulating films including the side wall insulating film 11, the liner insulating film 12, and the insulating film 13a, and the upper surface of the semiconductor layer 23 is exposed in the recess portion H.

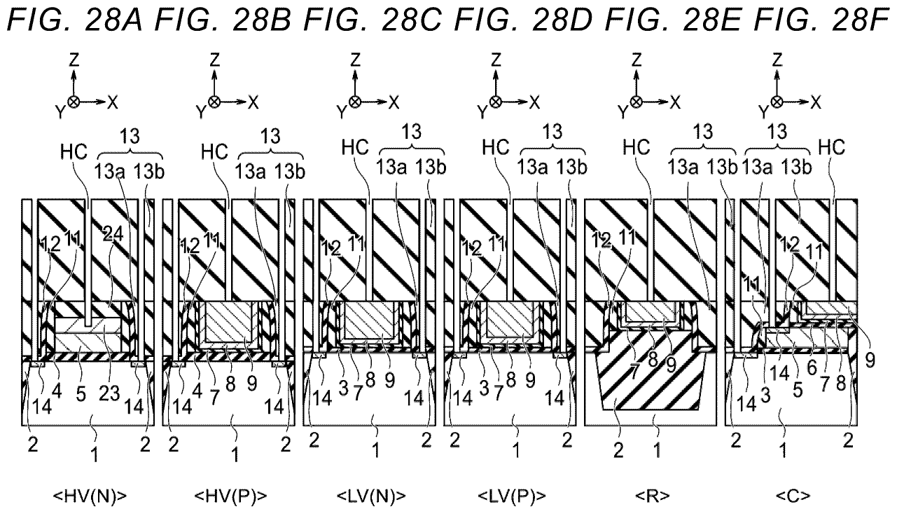

Subsequently, the processes illustrated in FIGS. 19A to 19F, FIGS. 20A to 20F, . . . , and FIGS. 25A to 25F are performed. As a result, the plurality of contact holes HC are formed in the interlayer insulating film 13 (FIGS. 28A to 28F). Each contact hole HC is formed to reach the upper surface of the silicide region 14 or the electrode material layer 9. Here, the contact hole HC illustrated in the middle of FIG. 28A is formed to penetrate through the cap layer 24 and reach the semiconductor layer 23. Thereafter, the contact plug 15 is formed in each contact hole HC (see FIGS. 1A to 1F).

When the process of forming the silicide region 14 is omitted in the processes illustrated in FIGS. 14A to 14F, the silicide region 14 may be formed from the contact hole HC in the substrate 1, the semiconductor layer 5, and the semiconductor layer 23 in the processes illustrated in FIGS. 28A to 28F.

In this way, the semiconductor device according to the embodiment is manufactured. Specifically, the transistors HV(N), HV(P), LV(N), and LV(P), the resistor R, and the capacitor C are formed in the regions illustrated in FIGS. 28A to 28F.

According to the modified example, the gate electrode of the transistor HV(N) can be formed with the semiconductor layers 5 and 23. Similarly, in the modified example, the gate electrode of the transistor HV(P), the gate electrode of the transistor LV(N), the gate electrode of the transistor LV(P), or the conductive layers of the resistor R may be formed with the semiconductor layers 5 and 23.

### (2) Second Modified Example

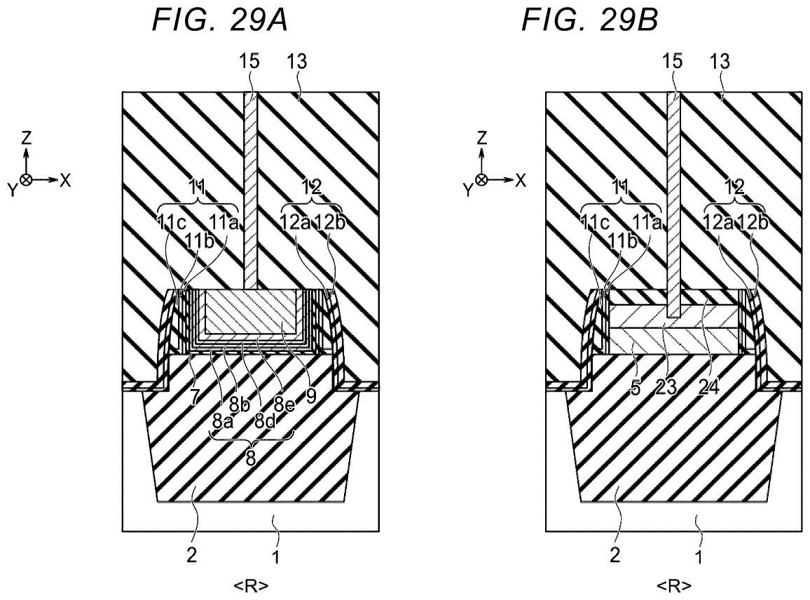

FIGS. 29A and 29B are sectional views illustrating a structure of a semiconductor device according to a second modified example of the first embodiment.

FIGS. 29A and 29B illustrate two resistors R formed on the same substrate 1. The resistor R illustrated in FIG. 29A includes conductive layers formed with metal layers (the electrode material ground layer 8 and the electrode material layer 9) similarly to the conductive layer of the resistor R illustrated in FIG. 1E, 4A, or 25E. Meanwhile, the resistor R illustrated in FIG. 29B includes conductive layers formed with the semiconductor layers (the semiconductor layers 5 and 23) similarly to the gate electrode of the transistor HV(N) illustrated in FIG. 28A.

According to the modified example, two types of resistors R formed with different materials can be formed on the same substrate 1. The resistor R illustrated in FIG. 29B can be formed, for example, by diverting the process of forming the gate electrode of the transistor HV(N) according to the first modified example to the process of forming the conductive layer of the resistor R.

When the resistor R is applied to a circuit in which a variation in resistance is required to be small, the resistor R is preferably formed of a metal material. On the other hand, the resistor R is preferably formed of a semiconductor material when the resistor R is applied to a circuit in which variation in resistance may be large and a circuit area is required to be small. When the semiconductor device according to the modified example includes the former circuit and the latter circuit, the structure of FIG. 29A may be applied to the former resistor R and the structure of FIG. 29B may be applied to the latter resistor R.

### (3) Third Modified Example

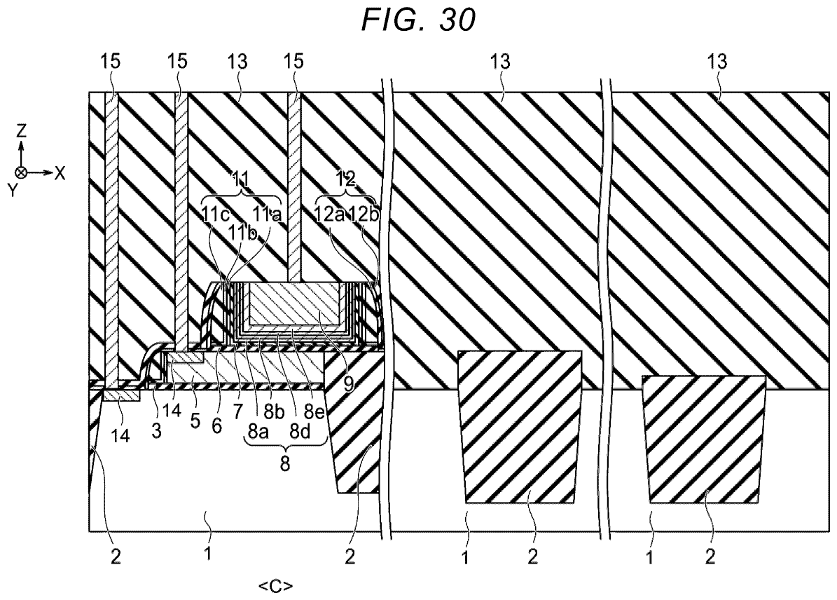

FIG. 30 is a sectional view illustrating a structure of a semiconductor device according to a third modified example of the first embodiment.

FIG. 30 illustrates the capacitor C and two element isolation areas 2 formed in the vicinity of the capacitor C as in FIG. 4B. FIG. 30 further illustrates two element isolation areas 2 formed away from the capacitor C. Hereinafter, for the two element isolation areas 2, the element isolation area 2 on the left side is referred to as a “left element isolation area 2” and the element isolation area 2 on the right side is referred to as a “right element isolation area 2”.

In FIG. 30, the upper surface of the left element isolation area 2 is provided at a high location and the upper surface of the right element isolation area 2 is provided at a low location. In this way, the element isolation areas 2 according to the modified example may include upper surfaces of different heights. For example, the height of the upper surface of the left element isolation area 2 is the same as the height of the uppermost surface of the element isolation area 2 illustrated in FIG. 1E. On the other hand, the height of the upper surface of the right element isolation area 2 is higher than the height of the upper surface of the substrate 1 in FIG. 30, but may be same as the height of the upper surface of the substrate 1.

A difference in the heights of the upper surfaces of the element isolation areas 2 can occur, for example, when the semiconductor device is manufactured in the processes illustrated in FIGS. 7A to 25F. For example, in the processes illustrated in FIGS. 14A to 14F, the upper surface of a part of the element isolation area 2 formed on the substrate 1 is etched and the upper surface of another part of the element isolation area 2 formed on the substrate 1 is not etched in some cases. As a result, the left element isolation area 2 and the right element isolation area 2 illustrated in FIG. 30 are formed on the same substrate 1 in some cases.

The upper surface of the substrate 1 illustrated in FIG. 30 has the same height as the upper surface of the substrate 1 illustrated in FIGS. 1C to 1F. In FIG. 30, a difference in height between the upper surface of the substrate 1 and the upper surface of the right element isolation area 2 may be less than a difference in height between the upper surface of the right element isolation area 2 and the upper surface of the semiconductor layer 5.

In FIG. 30, the element isolation area 2 adjacent to the right side of the capacitor C is in contact with the capacitor C. In FIG. 30, a difference in height between the upper surface of the semiconductor layer 5 and the upper surface of the element isolation area 2 is less than a difference in height between the upper surface of the element isolation area 2 and the upper surface of the substrate 1. In the example illustrated in FIG. 30, the difference in height between the upper surface of the semiconductor layer 5 and the upper surface of the element isolation area 2 becomes substantially zero. The upper surface of the element isolation area 2 is an example of a fifth upper surface.

### (4) Fourth Modified Example

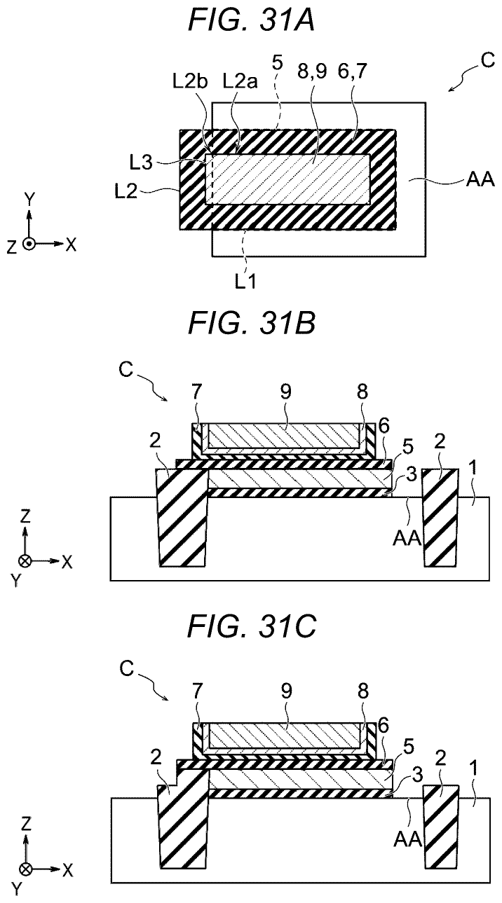

FIGS. 31A to 31C are plan and sectional views illustrating a structure of a semiconductor device according to a fourth modified example of the first embodiment.

FIGS. 31A and 31B are a plan view and a sectional view illustrating the structure of the capacitor C according to the modified example. FIG. 31B corresponds to FIG. 1F, and the side wall insulating film 11, the liner insulating film 12, the interlayer insulating film 13, the silicide region 14, and the contact plug 15 are not illustrated.

FIG. 31A illustrates a contour L1 of the intermediate electrode layer (the semiconductor layer 5), a contour L2 of the upper dielectric layer (the insulating films 6 and 7), and a contour L3 of the upper electrode layer (the electrode material ground layer 8 and the electrode material layer 9) in a top view. In the modified example, shapes of the contours L1 to L3 are all rectangular. In the modified example, the contour L2 of the upper dielectric layer includes a portion L2a located inside the contour L1 of the intermediate electrode layer and a portion L2b located outside of the contour L1 of the intermediate electrode layer and encloses the contour L3 of the upper electrode layer.

FIGS. 31A and 31B further illustrate a region AA that is a part of the substrate 1. The region AA is enclosed in a circular shape by the insulating film (for example, a SiO₂ film) forming the plurality of element isolation areas 2 illustrated in FIG. 31B in a top view. The insulating film 3, the semiconductor layer 5, the insulating film 6, the insulating film 7, the electrode material ground layer 8, and the electrode material layer 9 in the capacitor C according to the modified example are formed on the region AA. The region AA is referred to as an active area.

The semiconductor device according to the modified example may have a structure illustrated in FIG. 31C instead of the structure illustrated in FIG. 31B. In FIG. 31C, the insulating film 6 is removed from the upper surface of a part of the element isolation area 2 located to the left of the capacitor C and the upper surface of the element isolation area 2 located to the right of the capacitor C. As a result, the height of the upper surface is lowered due to an influence of etching.

As described above, according to the embodiment, when the devices such as the transistors HV(N), HV(P), LV(N), and LV(P), the resistor R, and the capacitor C are formed above the substrate 1, the devices that have appropriate performance can be formed. For example, by forming the resistor R above the element isolation area 2 that includes a surface higher than the upper surface of the substrate 1, it is possible to increase the value of the resistor R. By forming the capacitor C including the lower and upper capacitors, it is possible to increase the capacitance of the capacitor C.

### Second Embodiment

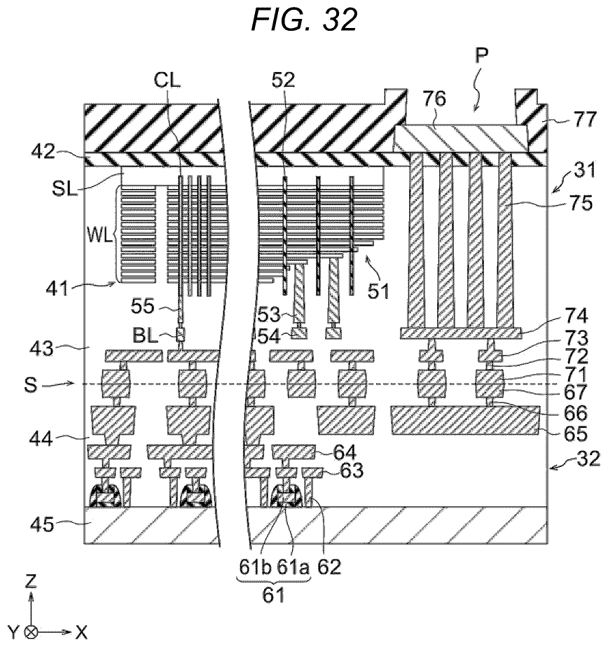

FIG. 32 is a sectional view illustrating a structure of a semiconductor device according to a second embodiment.

The semiconductor device according to the embodiment includes, for example, a 3-dimensional semiconductor memory. The semiconductor device according to the embodiment is manufactured by bonding an array wafer including an array chip 31 and a circuit wafer including a circuit chip 32 together, as will be described below. The semiconductor device according to the embodiment corresponds to an example of the semiconductor device according to the first embodiment.

The array chip 31 includes a memory cell array 41 including a plurality of memory cells, an insulating film 42 on the memory cell array 41, and an interlayer insulating film 43 below the memory cell array 41. The insulating film 42 is, for example, a SiO₂ film. The interlayer insulating film 43 is, for example, a stacked film including a SiO₂ film and an insulating film.

The circuit chip 32 is provided below the array chip 31. Reference sign S denotes a bonding surface of the array chip 31 and the circuit chip 32. The circuit chip 32 includes an interlayer insulating film 44 below the interlayer insulating film 43 and a substrate 45 below the interlayer insulating film 44. The interlayer insulating film 44 is, for example, a stacked film including a SiO₂ film and other insulating films. The substrate 45 is, for example, a semiconductor substrate such as a Si substrate. The substrate 45 according to the embodiment corresponds to an example of the substrate 1 according to the first embodiment, and the interlayer insulating film 44 according to the embodiment corresponds to an example of the interlayer insulating film 13 according to the first embodiment.

As illustrated in FIG. 32, the X and Y directions are vertical to each other in parallel to the surface of the substrate 45 and the Z direction is vertical to the surface of the substrate 45. The X, Y, and Z directions intersect with each other.

The array chip 31 includes a plurality of word lines WL as a plurality of electrode layers in the memory cell array 41. FIG. 32 illustrates a stair structure unit 51 in the memory cell array 41 and a plurality of beams 52 provided in the stair structure unit 51. Each word line WL is electrically connected to a word wiring layer 54 via a contact plug 53. Each columnar portion CL penetrating through the plurality of word lines WL is electrically connected to a bit line BL via a via plug 55 and is electrically connected to a source line SL. The bit line BL is provided below the plurality of word lines WL and the source line SL is provided above the plurality of word lines WL.

The circuit chip 32 includes a plurality of transistors 61. Each transistor 61 includes a gate insulating film 61a and a gate electrode 61b provided in order above the substrate 45, and a source diffusion layer and a drain diffusion layer (not illustrated) provided in the substrate 45. The circuit chip 32 includes a plurality of contact plugs 62 provided above the gate electrodes 61b, the source diffusion layers, or the drain diffusion layers of the plurality of transistors 61. The circuit chip 32 includes wiring layers 63, 64, and 65. The wiring layer 63 includes a plurality of wirings and is provided above the plurality of contact plugs 62. The wiring layer 64 includes a plurality of wirings and is provided above the wiring layer 63. The wiring layer 65 includes a plurality of wirings and is provided above the wiring layer 64.

The circuit chip 32 further includes a plurality of via plugs 66 provided above the wiring layer 65 and a plurality of metal pads 67 provided above the plurality of via plugs 66. The metal pad 67 is, for example, a metal layer containing copper (Cu) layer. The circuit chip 32 functions as a circuit that controls an operation of the array chip 31. This circuit includes the transistors 61 and is electrically connected to the metal pads 67.

The plurality of transistors 61 according to the embodiment includes the transistors HV(N), HV(P), LV(N), and LV(P) according to the first embodiment. The transistors HV(N), HV(P), LV(N), and LV(P) configure the circuit. The circuit further includes the resistor R or the capacitor C according to the first embodiment. The contact plug 62 according to the embodiment corresponds to an example of the contact plug 15 according to the first embodiment.

The array chip 31 includes a plurality of metal pads 71 provided above the plurality of metal pads 67 and a plurality of via plugs 72 provided above the plurality of metal pads 71. The metal pads 71 are, for example, metal layers including Cu layers. The array chip 31 includes wiring layers 73 and 74. The wiring layer 73 includes a plurality of wirings and is provided above the plurality of via plugs 72. The wiring layer 74 includes a plurality of wirings and is provided above the wiring layer 73. The bit line BL is provided in the wiring layer 74. The circuit is electrically connected to the memory cell array 41 via the metal pads 71 and 67 and the like and controls an operation of the memory cell array 41 via the metal pads 71 and 67 and the like.

The array chip 31 includes a plurality of via plugs 75 provided above the wiring layer 74 and a metal pad 76 provided above the plurality of via plugs 75 or the insulating film 42. The array chip 31 includes a passivation insulating film 77 provided above the metal pad 76 or the insulating film 42. The metal pad 76 is, for example, a metal layer including a Cu layer and functions as an external connection pad (bonding pad) of the semiconductor device according to the embodiment. The passivation insulating film 77 is, for example, a stacked film including a SiO₂ film and a SiN film and includes an opening P for exposing the upper surface of the metal pad 76. The metal pad 76 can be electrically connected to a mount substrate or another device by a bonding wire, a soldering ball, a metal pump, or the like via the opening P.

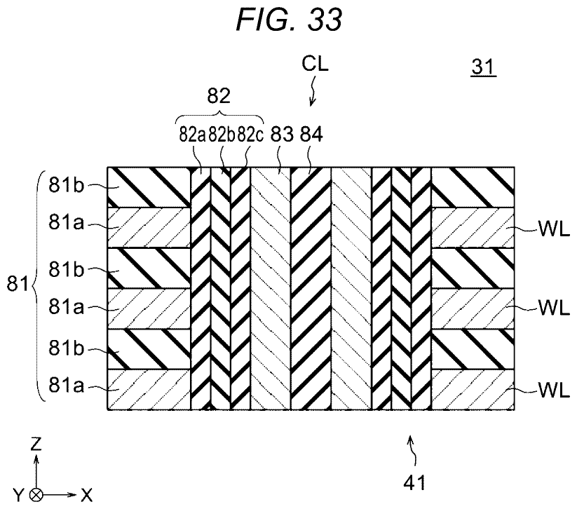

FIG. 33 is an enlarged sectional view illustrating the structure of the semiconductor device according to the second embodiment.

FIG. 33 illustrates the memory cell array 41 illustrated in FIG. 32. The memory cell array 41 includes a stacked film 81 that includes a plurality of electrode layers 81a and a plurality of insulating films 81b stacked alternately in the Z direction. The plurality of electrode layers 81a function as, for example, the word lines WL. Each electrode layer 81a is, for example, a metal layer including a W layer. Each insulating film 81b is, for example, a SiO₂ film.

FIG. 33 further illustrates one of the plurality of columnar portions CL illustrated in FIG. 32. Each columnar portion CL includes a memory insulating film 82, a channel semiconductor layer 83, and a core insulating film 84 provided in order on a side surface of the stacked film 81. The memory insulating film 82 includes a block insulating film 82a, a charge storage layer 82b, and a tunnel insulating film 82c provided in order on the side surface of the stacked film 81. The block insulating film 82a is, for example, a SiO₂ film. The charge storage layer 82b is, for example, an insulating film such as a SiN film. The charge storage layer 82b may be a semiconductor layer such as a polysilicon layer. The tunnel insulating film 82c is, for example, a SiO₂ film. The channel semiconductor layer 83 is, for example, a polysilicon layer. The channel semiconductor layer 83 functions as a channel of the memory cell. The core insulating film 84 is, for example, a SiO₂ film.

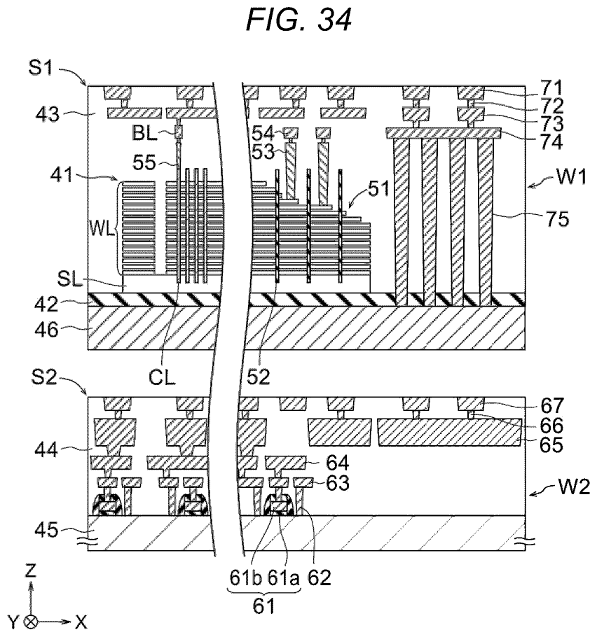

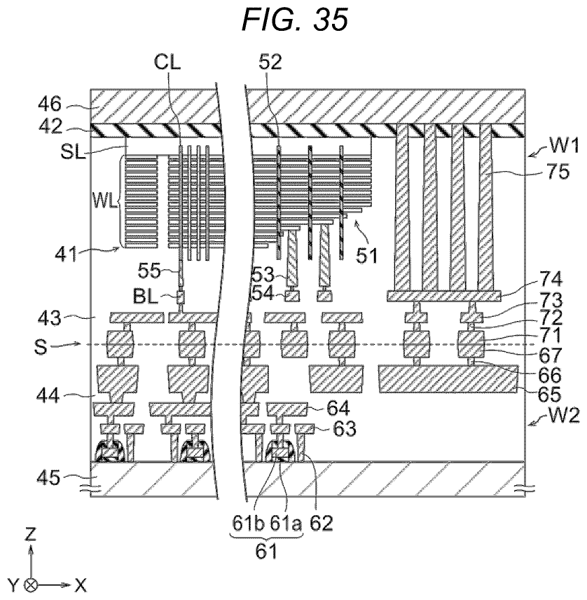

FIGS. 34 and 35 are sectional views illustrating a method of manufacturing the semiconductor device according to the second embodiment.

FIG. 34 illustrates an array wafer W1 including the plurality of array chips 31 and a circuit wafer W2 including the plurality of circuit chips 32. A direction of the array wafer W1 in FIG. 34 is reverse to a direction of the array chip 31 in FIG. 32. In the embodiment, the semiconductor device is manufactured by bonding the array wafer W1 and the circuit wafer W2 together. FIG. 34 illustrates the array wafer W1 before the direction is reversed for bonding and FIG. 32 illustrates the array chip 31 after the direction is reversed for bonding and the bonding and dicing are performed.

In FIG. 34, reference sign S1 denotes an upper surface of the array wafer W1 and reference sign S2 denotes an upper surface of the circuit wafer W2. The array wafer W1 includes a substrate 46 provided below the insulating film 42. The substrate 46 is, for example, a semiconductor substrate such as a Si substrate.

In the embodiment, as illustrated in FIG. 34, first, the memory cell array 41, the insulating film 42, the interlayer insulating film 43, the metal pad 71, and the like are formed above the substrate 46 of the array wafer W1, and the interlayer insulating film 44, the transistor 61, the metal pad 67, and the like are formed above the substrate 45 of the circuit wafer W2. Subsequently, as illustrated in FIG. 35, the array wafer W1 and the circuit wafer W2 are bonded by a mechanical pressure so that a surface S1 faces a surface S2. Accordingly, the interlayer insulating film 43 is adhered to the interlayer insulating film 44. Subsequently, the array wafer W1 and the circuit wafer W2 are annealed. Accordingly, the metal pad 71 is adhered to the metal pad 67. In this way, the substrates 46 and 45 are bonded via the interlayer insulating films 43 and 44.

Thereafter, the substrate 46 is removed by CMP, the substrate 45 is thinned by CMP, and then the array wafer W1 and the circuit wafer W2 are cut into a plurality of chips (dicing). In this way, the semiconductor device illustrated in FIG. 32 is manufactured. The metal pad 76 and the passivation insulating film 77 are formed on the insulating film 42 after the substrate 46 is removed and the substrate 45 is thinned.

FIG. 32 illustrates a boundary surface between the interlayer insulating films 43 and 44 or a boundary surface between the metal pads 71 and 67, but the boundary surfaces may become unobservable after the above annealing. However, locations of the boundary surfaces can be estimated, for example, by detecting an inclination of the side surface of the metal pad 71 or the side surface of the metal pad 67 and location misalignment between the side surface of the metal pad 71 and the side surface of the metal pad 67.

According to the embodiment, by applying the semiconductor device according to the first embodiment to a 3-dimensional semiconductor memory, it is possible to form a device that has appropriate performance as a device for a 3-dimensional semiconductor memory.

### Third Embodiment

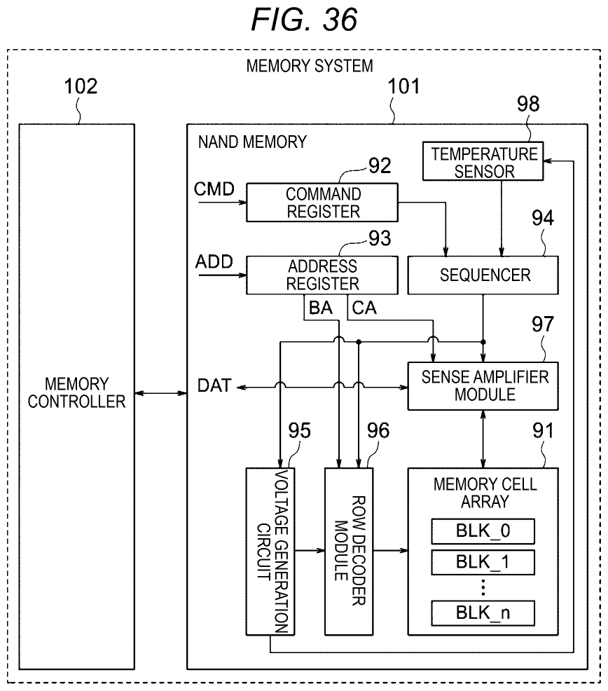

FIG. 36 is a block diagram illustrating a configuration of a memory system according to a third embodiment.

The memory system according to the embodiment includes a NAND memory 101 and a memory controller 102. The NAND memory 101 includes a memory cell array 91, a command register 92, an address register 93, a sequencer 94, a voltage generation circuit 95, a row decoder module 96, a sense amplifier module 97, and a temperature sensor 98. The NAND memory 101 according to the embodiment corresponds to an example of the semiconductor device according to the second embodiment. The memory cell array 91 according to the embodiment corresponds to an example of the memory cell array 41 according to the second embodiment.

An operation of the NAND memory 101 is controlled by the memory controller 102. The memory controller 102 operates in response to a request from a host device (not illustrated). For example, the memory controller 102 controls reading of data from the NAND memory 101 in response to a read request from the host device. The memory controller 102 controls writing of data on the NAND memory 101 in response to a write request from the host device. The memory controller 102 controls erasing of data from the NAND memory 101 in response to an erase request from the host device.

The memory cell array 91 includes a plurality of blocks BLK. Each block BLK is a set including a plurality of memory cells capable of storing data in a nonvolatile manner. The block BLK is used, for example, as erasing units of data. On the other hand, a page to be described below is used, for example, as write units and read units of data. FIG. 36 illustrates n+1 blocks BLK_0 to BLK_n (where n is an integer of 1 or more) as examples of the blocks BLK. The memory cell array 91 further includes a plurality of bit lines and a plurality of word lines. Each memory cell is associated with one bit line and one word line.

The command register 92 stores a command CMD received from the memory controller 102 by the NAND memory 101. The command CMD includes, for example, commands to cause the sequencer 94 to execute a read operation, a write operation, an erasing operation, and the like.

The address register 93 stores address information ADD received from memory controller 102 by the NAND memory 101. The address information ADD includes, for example, a block address BA or a column address CA. The block address BA and the column address CA are each used during selection of a block BLK and a bit line.

The sequencer 94 controls an operation of the entire NAND memory 101. For example, the sequencer 94 controls operations of the voltage generation circuit 95, the row decoder module 96, the sense amplifier module 97 based on the command CMD stored in the command register 92. Accordingly, a read operation, a write operation, an erase operation, or the like are executed based on the command CMD.

The voltage generation circuit 95 generates a voltage used for a read operation, a write operation, an erase operation, or the like under the control of the sequencer 94. For example, the voltage generation circuit 95 applies the generated voltage to a signal line corresponding to the selected word line. The voltage generation circuit 95 generates a power voltage of the temperature sensor 98 and applies the power voltage to the temperature sensor 98.

The row decoder module 96 selects the block BLK based on the block address BA stored in the address register 93 and transmits a voltage applied to a signal line corresponding to the selected word line to the word line selected in the selected block BLK.

During a write operation, the sense amplifier module 97 transmits write data received from the memory controller 102 to the memory cell array 91. During a read operation, the sense amplifier module 97 determines a value stored in each memory cell based on a voltage of a bit line and transmits a result of the determination as read data DAT to the memory controller 102.

The temperature sensor 98 detects a temperature of the NAND memory 101. The temperature sensor 98 generates temperature information based on the detected temperature and transmits the temperature information to the sequencer 94. The temperature information is used for the sequencer 94 to correct a voltage generated by the voltage generation circuit 95, for example, during a write operation, a read operation, an erase operation, or the like.

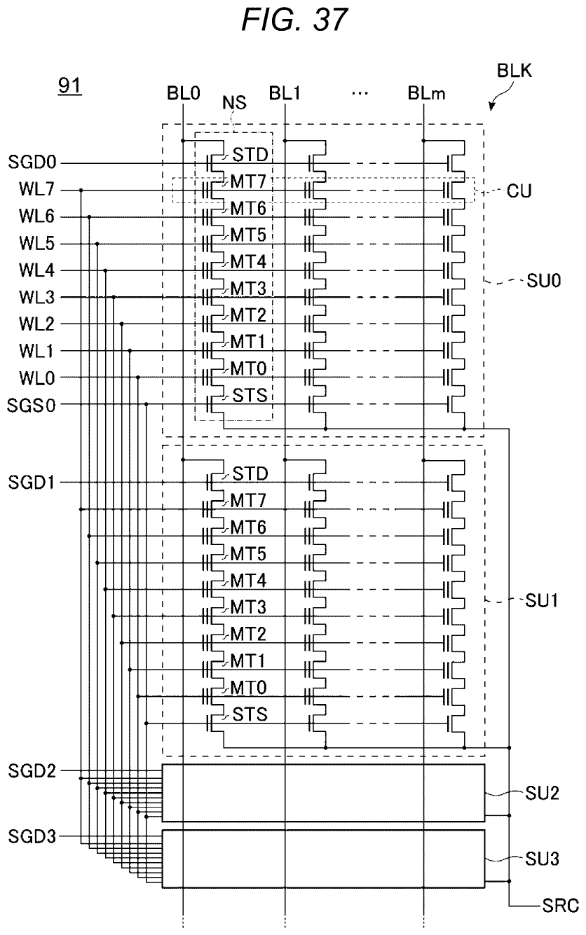

FIG. 37 is a circuit diagram illustrating a configuration of the memory cell array 91 according to the third embodiment. FIG. 37 illustrates one of the plurality of blocks BLK in the memory cell array 91. Each block BLK according to the embodiment includes a plurality of string units SU0 to SU3, as illustrated in FIG. 37. Each of the string units SU0 to SU3 includes m+1 NAND strings NS (where m is an integer of 1 or more) between m+1 bit lines BL0 to BLm and one source line SRC. Hereinafter, each of the string units SU0 to SU3 is also referred to as a “string unit SU” and each of the bit lines BL0 to BLm is also referred to as the “bit line BL”.

In the string unit SU0, the NAND string NS between the bit line BL0 and the source line SRC includes memory cell transistors (memory cells) MT0 to MT7 above the word lines WL0 to WL7. The NAND string NS further includes a select transistor STS above a source-side selection line SGS0 and includes a select transistor STD above a drain-side selection line SGD0. In the embodiment, the other NAND strings NS in the memory cell array 91 have the same structure. Hereinafter, each of the word line WL0 to WL7 is also referred to as the “word line WL”, each of the memory cell transistors MT0 to MT7 is also referred to as a “memory cell transistor MT”, and each of the select transistors STS and STD is also referred to as a “select transistor ST”. The NAND string NS in the string unit SU0 includes a select transistor STS above a source-side selection line SGS0 and includes a select transistor STD above a drain-side selection line SGD1. The string unit SU2 includes a drain-side selection line SGD2. The string unit SU3 includes a drain-side selection line SGD3.

Each block BLK according to the embodiment includes a plurality of cell units CU. Each cell unit CU includes a plurality of memory cell transistors MT provided above one word line WL in one string unit SU. Accordingly, each cell unit CU in FIG. 37 includes m+1 memory cell transistors MT. Each cell unit CU corresponds to one page. In each cell unit CU, each word line WL is commonly electrically connected to each gate of the m+1 memory cell transistors MT.

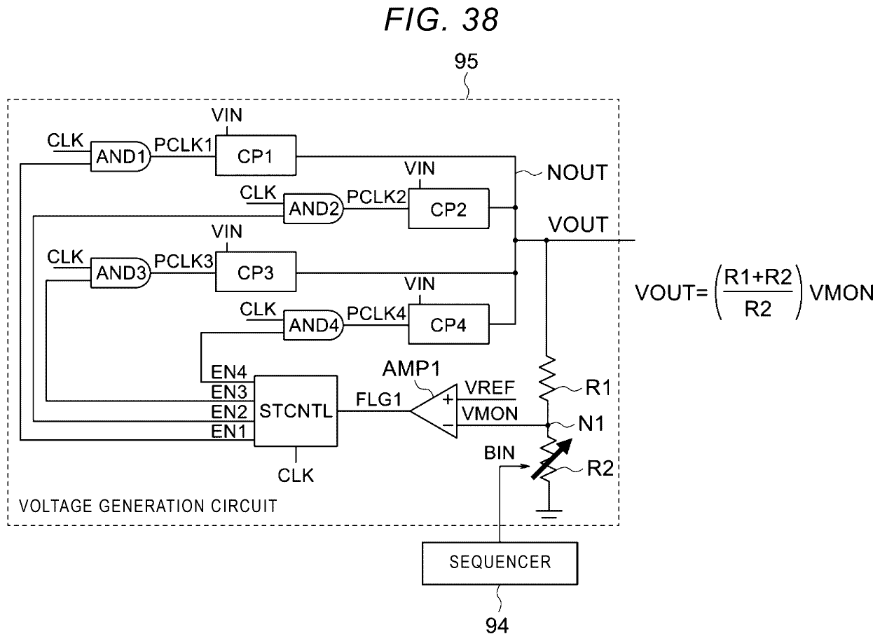

FIG. 38 is a circuit diagram illustrating a configuration of the voltage generation circuit 95 according to the third embodiment.

As illustrated in FIG. 38, the voltage generation circuit 95 includes a plurality of charge pumps CP1 to CP4, a plurality of resistors R1 and R2, an operational amplifier AMP1, a state control circuit STCNTL, and a plurality of logic gates (AND gates) AND1 to AND4. FIG. 38 further illustrates a node NOUT and a node N1 in the voltage generation circuit 95.

When a voltage VIN is input to the voltage generation circuit 95, the voltage generation circuit 95 generates a voltage VOUT higher than the voltage VIN and outputs the voltage VOUT from the node NOUT. The voltage VIN is supplied, for example, from a voltage source in the NAND memory 101 to the voltage generation circuit 95. The voltage VOUT is used, for example, for a read operation, a write operation, an erase operation, or the like.

A signal BIN illustrated in FIG. 38 is output from the sequencer 94 and is input to the voltage generation circuit 95. The signal BIN is a control signal used for the sequencer 94 to control an operation of the voltage generation circuit 95 and is, for example a digital signal. As will be described below, a waveform of the voltage VOUT varies in accordance with information retained by the signal BIN. Accordingly, the sequencer 94 can vary the waveform of the voltage VOUT by controlling the information retained by the signal BIN.

Next, details of each element in the voltage generation circuit 95 will be described continuously with reference to FIG. 38.

The charge pump CP1 includes an input terminal to which the voltage VIN is input, an input terminal to which a signal PCLK1 is input, and an output terminal electrically connected to the node NOUT. The same applies to the charge pumps CP2 to CP4. Here, each of the charge pumps CP2 to CP4 includes input terminals to which signals PCLK2 to PCLK4 are input instead of the signal PCLK1. Hereinafter, each of the charge pumps CP1 to CP4 is also referred to as a “charge pump CP” and each of the signals PCLK1 to PCLK4 is also referred to as a “signal PCLK”.

Each charge pump CP performs a boosting operation while the signal PCLK input to the charge pump CP is a clock signal CLK and the sequencer 94 does not collectively prohibit the boosting operation of all the charge pumps CP. For example, when the voltage VOUT is higher than a collective prohibition threshold of a boosting operation, the sequencer 94 collectively prohibits the boosting operation of all the charge pumps CP. When the signal PCLK input to a certain charge pump CP is the clock signal CLK and the charge pump CP is designated as a pump that can perform the boosting operation by the state control circuit STCNTL, a state of the charge pump CP is referred to as “active”. The active charge pump CP performs the boosting operation while the sequencer 94 does not collectively prohibit the boosting operation of all the charge pumps CP.

On the other hand, each charge pump CP stops the boosting operation while the signal PCLK input to the charge pump CP is not the clock signal CLK or the sequencer 94 collectively prohibits the boosting operation of all the charge pumps CP. When the signal PCLK input to a certain charge pump CP is not the clock signal CLK or the charge pump CP is designated as a pump that cannot perform the boosting operation by the state control circuit STCNTL, the state of the charge pump CP is referred to as “inactive”. The inactive charge pump CP stops the boosting operation even when the sequencer 94 does not collectively prohibit the boosting operation of all the charge pumps CP. An example of a case in which the signal PCLK input to the charge pump CP is not the clock signal CLK is a case in which a value of the signal PCLK is kept at a low (L) level, as will be described below.

The resistor R1 is disposed between the node NOUT and the node N1. The resistor R2 is disposed between the node N1 and a ground node. Accordingly, the resistors R1 and R2 are disposed in series between the node NOUT and the ground node.

The resistor R2 according to the embodiment is a variable resistor. A value of the resistor R2 can vary in accordance with the signal BIN. A relation of VOUT={(R1+R2)/R2}VMON holds between voltages VOUT and VMON.

The operational amplifier AMP1 includes a non-inverted input terminal to which a reference voltage VREF is input, a non-inverted input terminal to which the voltage VMON is input, and an output terminal from which a signal FLG1 is output. The signal FLG1 is generated based on a comparison result between the reference voltage VREF and the voltage VMON. For example, when the voltage VMON is less than the reference voltage VREF, a value of the signal FLG1 enters a high (H) level. Conversely, when the voltage VMON is equal to or greater than the reference voltage VREF, the value of the signal FLG1 enters a low (L) level.

The state control STCNTL includes an input terminal to which the signal FLG1 is input from the operational amplifier AMP1, an input terminal to which the clock signal CLK is input, and an output terminal from which each of signals EN1 to EN4 is output to each of logical gates AND1 to AND4. The state control circuit STCNTL uses the clock signal CLK to calculate a period NH in which the value of the signal FLG1 is kept at the H level and a period NL in which the value of the signal FLG1 is kept at the L level. The state control circuit STCNTL further generates the signals EN1 to EN4 based on the periods NH and NL. The signals EN1 to EN4 are used to designate whether the charge pumps CP1 to CP4 become active or inactive, respectively. Hereinafter, each of the signals EN1 to EN4 is also referred to as a “signal EN”.

When a value of the signal EN is at the H level, the signal EN is used to designate that the charge pump CP becomes active. Conversely, when the value of the signal EN is at the L level, the signal EN is used to designate that the charge pump CP becomes inactive. Based on the periods NH and NL, the state control circuit STCNTL controls the number Nu of signals EN having the value of the H level among the signals EN1 to EN4. A state of the state control circuit STCNTL transitions among four states S1 to S4 in accordance with the number Nu. The states S1 to S4 are states in which the number Nu is one to four, respectively.

The logical gate AND1 includes an input terminal to which the signal EN1 is input, an input terminal to which the clock signal CLK is input, and an output terminal from which the signal PCLK1 is output to the charge pump CP1. The signal PCLK1 indicates an AND operation result of the signal EN1 and the clock signal CLK. For example, when the value of the signal EN1 is at the H level, the signal PCLK1 becomes the clock signal CLK. Conversely, when the value of the signal EN1 is at the L level, the value of the signal PCLK1 is kept at the L level.

The same applies to the logical gates AND2 to AND4. Here, each of the logical gates AND2 to AND4 includes an input terminal to which each of the signals EN2 to EN4 is input instead of the signal EN1 and an output terminal from which each of the signals PCLK2 to PCLK4 is output instead of the signal PCLK1. Hereinafter, each of the logical gates AND1 to AND4 is also referred to as a “logical gate AND”.

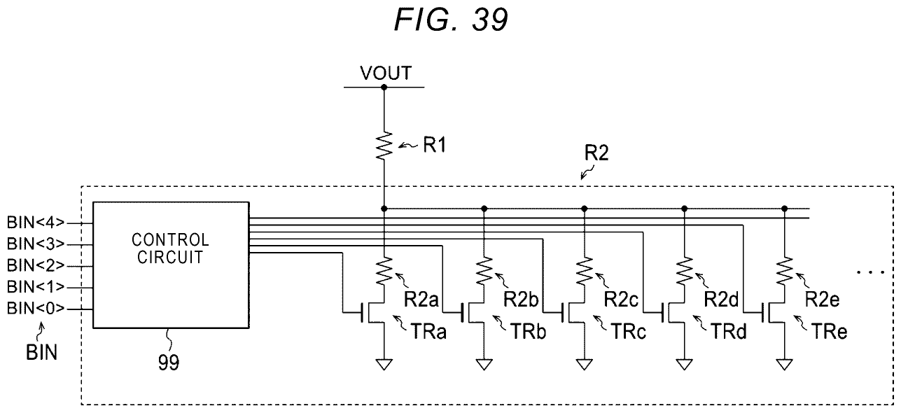

FIG. 39 is a circuit diagram illustrating a configuration of the resistor R2 according to the third embodiment.

The above-described resistor R2 includes a control circuit 99, N resistors such as resistors R2a to R2e, and N transistors such as transistors TRa to TRe (where N is an integer of 2 or more). The resistor R2 functions as a variable resistor by such circuit elements.

The resistors R2a to R2e are connected in parallel to the resistor R1. The transistors TRa to TRe are connected in series to the resistors R2a to R2e. Based on the signal BIN, the control circuit 99 outputs control signals for controlling the transistors TRa to TRe. The control signals for the transistors TRa to TRe are supplied to the gates of the transistors TRa to TRe, respectively. The same applies to resistors other than the resistors R2a to R2e or transistors other than the transistors TRa to TRe.

Based on the signal BIN, the control circuit 99 controls ON and OFF of N transistors in accordance with the above control signals. As a result, the value of the resistor R is determined by values of the resistors connected in series to the transistors that are turned on. Accordingly, the value of the resistor R2 can be varied in accordance with the signal BIN.

The signal BIN is, for example, an N-bit digital signal, and values “L level” and “H level” of each bit correspond to “OFF” and “ON” of a corresponding transistor. For example, when values of all bits enter the H level, N transistors are all turned on. In FIG. 39, BIN<0> to BIN<4>included in the signal BIN are exemplified. ON and OFF of the transistors TRa to TRe are controlled in accordance with BIN<0> to BIN<4>, respectively.

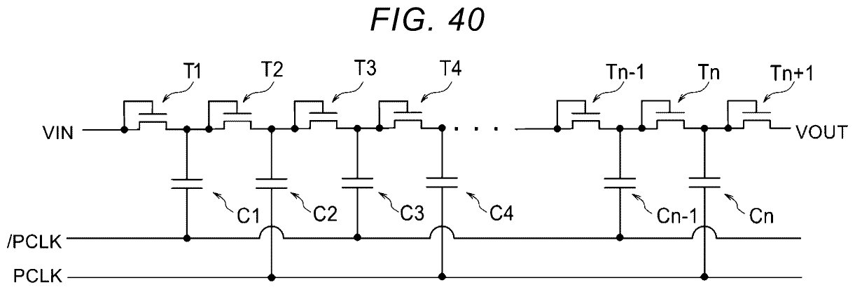

FIG. 40 is a circuit diagram illustrating a configuration of the charge pump CP according to the third embodiment.

The charge pump CP illustrated in FIG. 40 includes n+1 transistors T1 to Tn+1 (where n is an integer of 1 or more) disposed in series between an input terminal of the voltage VIN and an output terminal of the voltage VOUT. The charge pump CP illustrated in FIG. 40 further includes n capacitors C1 to Cn. One electrode of a capacitor Ck is electrically connected to a node between a transistor Tk and a transistor Tk+1 and the other electrode of the capacitor Ck is electrically connected to an input terminal of the signal PCLK or a signal/PCLK (where k is an integer satisfying 1≤k≤n). When a value of k is an odd number, the capacitor Ck is electrically connected to an input terminal of the signal/PCLK. When the value of k is an even number, the capacitor Ck is electrically connected to the input terminal of the signal PCLK.

Each of the capacitors C1 to Cn according to the embodiment is the capacitor C according to the first embodiment. Each of the transistors T1 to Tn+1 according to the embodiment may be one of the transistors HV(N), HV(P), LV(N), and LV(P) according to the first embodiment.

The transistors T1 to Tn+1 according to the embodiment may have a triple-well structure. For example, a P-type semiconductor substrate may include an N-type well, a P-type well may be provided in the N-type well, and the transistors T1 to Tn+1 may be provided in the P-type well.

According to the embodiment, by applying the semiconductor device according to the first embodiment to the NAND memory 101, it is possible to form a device that has appropriate performance as a device for the NAND memory 101. For example, the capacitor C that has appropriate performance can be formed as a capacitor for the charge pump CP. Accordingly, the charge pump CP handling a high voltage can be formed by the capacitor C capable of appropriately handling the high voltage.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a substrate including a first upper surface;
an element isolation area provided in the substrate and including a second upper surface that is higher than the first upper surface;
at least one transistor including a gate insulating film provided above the first upper surface of the substrate and a gate electrode provided above the gate insulating film;
a resistor including a conductive layer provided above the second upper surface of the element isolation area; and
a capacitor including a first dielectric layer provided above the first upper surface of the substrate, a first electrode layer provided above the first dielectric layer, a second dielectric layer provided above the first electrode layer, and a second electrode layer provided above the second dielectric layer.

2. The semiconductor device according to claim 1,
wherein the gate insulating film includes one or more insulating films, and
wherein at least one of the one or more insulating films is provided on a lower surface and a side surface of the gate electrode.

3. The semiconductor device according to claim 1,
wherein the first upper surface of the substrate includes a third upper surface and a fourth upper surface that is higher than the third upper surface,
wherein the at least one transistor includes a first transistor including the gate insulating film provided above the third upper surface and a second transistor including the gate insulating film provided above the fourth upper surface,
wherein a thickness of the gate insulating film in the first transistor is higher than a thickness of the gate insulating film in the second transistor, and
wherein the second upper surface of the element isolation area is higher than the third upper surface and is higher than the fourth upper surface.

4. The semiconductor device according to claim 1,
wherein the gate insulating film contains a metal element, and
wherein the second dielectric layer contains the metal element.

5. The semiconductor device according to claim 1,
wherein the conductive layer is provided above the second upper surface of the element isolation area with one or more insulating films interposed therebetween, and
wherein at least one of the one or more insulating films is provided on a lower surface and a side surface of the conductive layer.

6. The semiconductor device according to claim 1,
wherein the element isolation area provided in the substrate and adjacent to the capacitor includes a fifth upper surface higher than the first upper surface, and
wherein a difference in height between the fifth upper surface and an upper surface of the first electrode layer is less than a difference in height between the fifth upper surface and the first upper surface.

7. The semiconductor device according to claim 1,
wherein the second dielectric layer includes one or more insulating films, and
wherein at least one of the one or more insulating films is provided on a lower surface and a side surface of the second electrode layer.

8. The semiconductor device according to claim 1, wherein the first electrode layer includes a semiconductor layer and the second electrode layer includes a metal layer.

9. The semiconductor device according to claim 1, wherein a height of an upper surface of the first electrode layer is equal to a height of the second upper surface of the element isolation area.

10. The semiconductor device according to claim 1,
wherein a height of a lower surface of the second electrode layer is higher than a height of the second upper surface of the element isolation area.

11. The semiconductor device according to claim 1,
wherein the capacitor is provided in a charge pump.

12. The semiconductor device according to claim 1,
wherein the gate insulating film in the at least one transistor includes a first insulating film and a second insulating film provided above the first insulating film,
wherein the first dielectric layer in the capacitor includes a third insulating film formed of a material that is the same as a material of the first insulating film, and
wherein the second dielectric layer in the capacitor includes a fourth insulating film formed of a material that is the same as a material of the second insulating film.

13. The semiconductor device according to claim 12, wherein the conductive layer in the resistor is provided above the second upper surface of the element isolation area with a fifth insulating film formed of a material that is the same as the material of the second insulating film interposed therebetween.

14. The semiconductor device according to claim 12, wherein the second dielectric layer in the capacitor further includes a sixth insulating film provided below the fourth insulating film.

15. The semiconductor device according to claim 1,
wherein the gate electrode in the at least one transistor includes a first conductive layer and a second conductive layer provided above the first conductive layer,
wherein the conductive layer in the resistor includes the first conductive layer and the second conductive layer, and
wherein the second electrode layer in the capacitor includes the first conductive layer and the second conductive layer.

16. A semiconductor device comprising:
a substrate;
a first dielectric layer provided above the substrate in a first direction;
a first electrode layer provided above the first dielectric layer such that a first capacitor is formed between the substrate and the first electrode layer;
a second dielectric layer provided above the first electrode layer; and
a second electrode layer provided above the second dielectric layer such that a second capacitor is formed between the second electrode layer and the first electrode layer,
wherein the second dielectric layer includes one or more insulating films, and
wherein at least one of the one or more insulating films is provided on a lower surface and a side surface of the second electrode layer.

17. The semiconductor device according to claim 16, wherein, when viewed from the first direction, a contour of the second dielectric layer includes a portion located inside a contour of the first electrode layer and a portion located outside of the contour of the first electrode layer and encloses a contour of the second electrode layer.

18. A method of manufacturing a semiconductor device, the method comprising:
forming a first dielectric layer above a substrate;
forming a first electrode layer above the first dielectric layer and forming a first capacitor between the substrate and the first electrode layer;
forming a second dielectric layer above the first electrode layer;
forming a first layer above the second dielectric layer;
forming an insulating film on a side surface of the first layer;
removing the first layer after forming the insulating film; and
after removing the first layer, forming a second electrode layer above the second dielectric layer in the insulating film and forming a second capacitor between the first electrode layer and the second electrode layer.

19. The method of manufacturing the semiconductor device according to claim 18,
wherein before the first layer is formed, a first portion of the second dielectric layer is formed above the first electrode layer,
wherein after the first layer is removed, a second portion of the second dielectric layer is formed above the first portion in the insulating film, and
wherein the second electrode layer is formed above the second portion in the insulating film.

20. The method of manufacturing the semiconductor device according to claim 18, further comprising:
after forming the first electrode layer, forming an element isolation area in the substrate, the first electrode layer, and the first dielectric layer,
wherein the second dielectric layer is formed after the element isolation area is formed.
